(19) United States
(12) Patent Application Publication
(10) Pub. No.: US 2011/0284830 A1
(43) Pub. Date: Nov. 24, 2011

(54) POLYMER AND POLYMER-NANOPARTICLE COMPOSITIONS

(76) Inventors: Zhang-Lin Zhou, Palo Alto, CA (US); Lihua Zhao, Sunnyvale, CA (US); Sity Lam, Pleasanton, CA (US); Gary Gibson, Palo Alto, CA (US); Jian Pei, Beijing (CN)

(21) Appl. No.: 13/146,400

(22) PCT Filed: Jan. 30, 2009
(86) PCT No.: PCT/US2009/032509

§ 371 Date: Jul. 26, 2011

(51) Int. Cl. H01L 51/54; C08L 65/00; C08G 61/10; B82Y 30/00

(52) U.S. Cl. 257/40; 528/8; 525/389; 524/610; 977/773; 257/E51.026

(57) ABSTRACT

A polymer-nanoparticle composition of formula II includes a polymer of formula I. The polymer has two portions. One portion of the polymer includes a binding group that binds to a nanoparticle. The other portion of the polymer includes a hydrophobic moiety.

### CROSS-REFERENCE TO RELATED APPLICATIONS

N/A

### STATEMENT REGARDING FEDERALLY SPONSORED RESEARCH OR DEVELOPMENT

N/A

### BACKGROUND

1. Technical Field

This invention relates to functionalized polymers and functionalized polymer-nanoparticle compositions, to devices employing the functionalized polymer-nanoparticle compositions and to methods of rendering particles, for example, nanoparticles, more stable in a non-polar medium and of enhancing the homogeneity of a mixture of such particles in non-polar medium.

2. Description of Related Art

Nanoparticle-polymer composite materials are polymer-based materials that include a plurality of nanoparticles or nanocrystals. Typically, the nanoparticles are randomly dispersed throughout the polymer matrix. Nanoparticle-polymer composite materials have been used, or proposed for use, in many electronic and optoelectronic devices including, for example, light-emitting diodes (LED's), information display devices, electromagnetic radiation sensors, lasers, photovoltaic cells, photo-transistors and modulators. However, nanoparticle-polymer composite materials tend to lack stability for use in many of these applications.

### SUMMARY

An embodiment of the present invention is a polymer that comprises repeating monomer units having the formula:

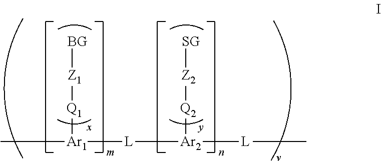

wherein:

BG is a binding group for binding to a nanoparticle,

Z₁ is independently a covalent bond or a chemical moiety providing a covalent bond between BG and Q₁,

Z₂ is independently a covalent bond or a chemical moiety providing a covalent bond between SG and Q₂,

Q₁ is a carbon atom or a heteroatom,

Q₂ is a carbon atom or a heteroatom,

Ar₁ is an aromatic ring moiety,

Ar₂ is an aromatic ring moiety,

L is independently a covalent bond directly linking Ar₁ and Ar₂ or a chemical moiety linking Ar₁ and Ar₂,

m and n are integers independently between 1 and about 5,000,

v is an integer greater than about 10,

x and y are integers independently between 1 and about 5,

SG is a hydrophobic moiety, with the proviso that if m is 1, then SG comprises at least 25 carbon atoms.

Another embodiment of the present invention is a polymer-nanoparticle composition having the formula:

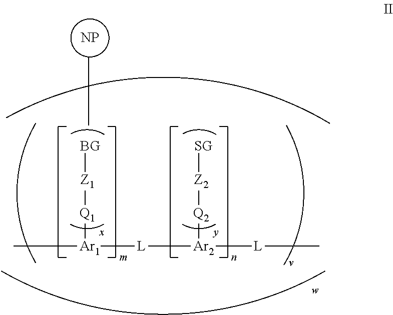

wherein:

BG is a binding group that is bound to a nanoparticle,

Z₁ is independently a covalent bond or a chemical moiety providing a covalent bond between BG and Q₁,

Z₂ is independently a covalent bond or a chemical moiety providing a covalent bond between SG and Q₂,

Q₁ is a carbon atom or a heteroatom,

Q₂ is a carbon atom or a heteroatom,

Ar₁ is an aromatic ring moiety,

Ar₂ is an aromatic ring moiety,

L is independently a covalent bond directly linking Ar₁ and Ar₂ or a chemical moiety linking Ar₁ and Ar₂,

w is an integer between about 2 and about 100,

m and n are integers independently between 1 and about 5,000,

v is an integer greater than about 10,

x and y are integers independently between 1 and about 5,

SG is a hydrophobic moiety, with the proviso that if m is 1, then SG comprises at least 25 carbon atoms, and

NP is a nanoparticle.

Another embodiment of the present invention is a device comprising a first electrode and a second electrode and a polymer-nanoparticle composition of formula II (mentioned above) disposed between the first electrode and the second electrode.

### BRIEF DESCRIPTION OF THE DRAWINGS

The drawings provided herein are for the purpose of facilitating the understanding of certain embodiments of the present invention and are provided by way of illustration and not limitation on the scope of the appended claims.

FIG. 1 is a scheme depicting a method of making a functionalized polymer in accordance with an embodiment of the present invention.

FIG. 2 is a scheme depicting a method of making a functionalized polymer in accordance with another embodiment of the present invention.

FIG. 3 is a scheme depicting a method of making a functionalized polymer in accordance with another embodiment of the present invention.

FIG. 4 is a scheme depicting a method of making embodiments of precursor reagents for preparing an embodiment of a functionalized polymer in accordance with the present invention.

FIG. 5 is a scheme depicting a method of making embodiments of other precursor reagents for preparing an embodiment of a functionalized polymer in accordance with the present invention.

FIG. 6 is a scheme depicting a method of making a functionalized polymer in accordance with another embodiment of the present invention.

FIG. 7 is a scheme depicting a method of making a functionalized polymer-nanoparticle composition in accordance with an embodiment of the present invention.

FIG. 8 is a scheme depicting a method of making a functionalized polymer-nanoparticle composition in accordance with another embodiment of the present invention.

FIG. 9 is a schematic diagram of an embodiment of a light-emitting device employing an embodiment of a functionalized polymer-nanoparticle composition in accordance with embodiments of the present invention.

FIG. 10 is a schematic diagram of another embodiment of a light-emitting device employing an embodiment of a functionalized polymer-nanoparticle composition in accordance with embodiments of the present invention.

FIG. 11 is a schematic diagram of another embodiment of a light-emitting device employing an embodiment of a functionalized polymer-nanoparticle composition in accordance with embodiments of the present invention.

FIG. 12 is a schematic diagram of another embodiment of a light-emitting device employing an embodiment of a functionalized polymer-nanoparticle composition in accordance with embodiments of the present invention.

### DETAILED DESCRIPTION

### General Discussion

Embodiments of the present methods and compositions facilitate one or more of enhancing the stability of particles, such as nanoparticles, in a medium, with enhancing the homogeneity of mixtures of such particles in a non-polar medium, and with enhancing the energy transfer between the functionalized polymer and nanoparticles. In some embodiments, each nanoparticle of a plurality of nanoparticles is chemically attached to a side chain of a functionalized polymer, which contains binding groups that can covalently attach to the nanoparticles, thus forming a chemical complex or a covalent bond between each of the nanoparticles and a binding group. In some embodiments, the functionalized polymers are designed to have two portions. One portion of the functionalized polymer has side chains wherein each side chain comprises binding groups that can covalently attach to nanoparticles, thus forming a chemical complex or a covalent bond between a nanoparticle and a binding group. The other portion of the functionalized polymer comprises side chains wherein each side chain has a bulky organic group that enhances the homogeneity of mixtures or solubility of the functionalized polymers so as to make the corresponding functionalized polymer-nanoparticle compositions soluble or well-dispersed in most common solvents, usually, organic non-polar solvents. Energy transfer between the functionalized polymer and nanoparticles is enhanced by better dispersion of the nanoparticles within a polymer matrix with a coordination bond between nanoparticles and the functionalized polymers of the present embodiments. The functionalized polymer comprises aromatic ring moieties in a polymer backbone of the polymer. In some embodiments, the aromatic ring moieties are linked by a chemical moiety that is a double or a triple bond, or that comprises at least one double bond or at least one triple bond.

In some embodiments, the functionalized polymer is a block copolymer where one of the blocks of the copolymer is functionalized to bind to the particles and the other of the blocks of the copolymer is functionalized to stabilize the particles and to control the homogeneity of mixtures of the particles in a non-polar medium. In some embodiments, the block copolymer comprises two block units or co-blocks. The first block unit comprises repeating units of a monomer comprising a binding group that binds to the particles. The second block unit comprises repeating units of a monomer comprising a hydrophobic moiety that provides steric stabilization and homogeneity of mixtures of the particles in a non-polar medium. In some embodiments, the number of monomers in each of the block units is controlled during the preparation of the functionalized polymer by controlling the molar concentration of the monomer units that are employed in the preparation of the polymer. Thus, the number of the binding groups and the number of stability enhancing and homogeneity enhancing groups are controlled in the final functionalized polymer. The functionalized polymer may be tailored to the particular nanoparticle, its composition and its use.

### Specific Embodiments of Polymers

In some embodiments, the polymer comprises repeating monomer units having the formula:

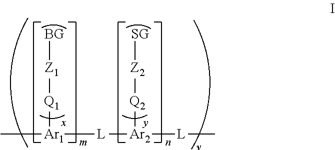

wherein:

BG is a binding group for binding to a nanoparticle,

Z₁ is independently a covalent bond or a chemical moiety providing a covalent bond between BG and Q₁,

Z₂ is independently a covalent bond or a chemical moiety providing a covalent bond between SG and Q₂,

Q₁ is a carbon atom or a heteroatom,

Q₂ is a carbon atom or a heteroatom,

Ar₁ is an aromatic ring moiety,

Ar₂ is an aromatic ring moiety,

L is independently a covalent bond directly linking Ar₁ and Ar₂ or a chemical moiety linking Ar₁ and Ar₂; in some embodiments, L is a double bond or triple bond or comprises at least one double bond or at least one triple bond such that the block copolymers exhibit semi-conducting properties.

m and n are integers independently between 1 and about 5,000; in some embodiments m and n are 1; in some embodiments m and n are at least 2,

v is an integer greater than about 10,

x and y are integers independently between 1 and about 5, or between 1 and about 4, or between 1 and about 3, or between 1 and 2, or between 2 and about 5, or between 2 and about 4, or between 2 and 3, between 3 and about 5, or between 3 and about 4, or between 4 and about 5, and

SG is a hydrophobic moiety that provides for steric stabilization and homogeneity of mixtures of the nanoparticle in a non-polar medium with the proviso that if m is 1, then SG comprises at least 25 carbon atoms.

Each of the repeating monomer units may be referred to as blocks; since the blocks are different from one another, the polymer may be referred to as a block copolymer.

In some embodiments, m and n are 1 and the polymer comprises repeating monomer units having the formula:

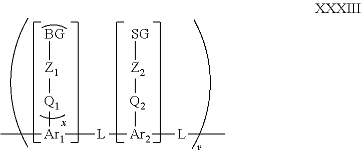

wherein BG, Z₁, Z₂, Q₁, Q₂, L, x, y and v are as defined above and SG comprises at least 25 carbon atoms.

In some embodiments, the aforementioned block copolymer comprises blocks of repeating monomer units and is of the formula:

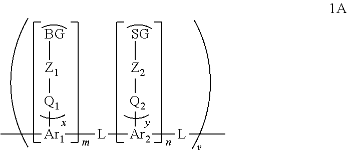

wherein:

BG is a binding group for binding to a nanoparticle,

Z₁ is independently a covalent bond or a chemical moiety providing a covalent bond between BG and Q₁,

Z₂ is independently a covalent bond or a chemical moiety providing a covalent bond between SG and Q₂,

Q₁ is a carbon atom or a heteroatom,

Q₂ is a carbon atom or a heteroatom,

Ar₁ is an aromatic ring moiety,

Ar₂ is an aromatic ring moiety,

L is independently a covalent bond directly linking Ar₁ and Ar₂ or a chemical moiety linking Ar₁ and Ar₂,

m and n are integers independently between 2 and about 5,000; in some embodiments m and n are at least 2,

v is an integer greater than about 10,

x and y are integers independently between 1 and about 5, or between 1 and about 4, or between 1 and about 3, or between 1 and 2, or between 2 and about 5, or between 2 and about 4, or between 2 and 3, between 3 and about 5, or between 3 and about 4, or between 4 and about 5, and

SG is a hydrophobic moiety that provides for steric stabilization and homogeneity of mixtures of the nanoparticle in a non-polar medium.

Each of Ar₁ and Ar₂ is independently an aromatic ring moiety. The phrase “aromatic ring moiety” or “aromatic” as used herein includes monocyclic rings, bicyclic ring systems, and polycyclic ring systems, in which the monocyclic ring, or at least a portion of the bicyclic ring system or polycyclic ring system, is aromatic (exhibits, e.g., π-conjugation). The monocyclic rings, bicyclic ring systems, and polycyclic ring systems of the aromatic ring moiety may include carbocyclic rings and/or heterocyclic rings. The term “carbocyclic ring” denotes a ring in which each ring atom is carbon. The term “heterocyclic ring” denotes a ring in which at least one ring atom is not carbon and comprises 1 to 4 heteroatoms.

By way of example and not limitation, each of Ar₁ and Ar₂ may be independently selected from the group consisting of: phenyl, fluorenyl, biphenyl, terphenyl, tetraphenyl, naphthyl, anthryl, pyrenyl, phenanthryl, thiophenyl, pyrrolyl, furanyl, imidazolyl, triazolyl, isoxazolyl, oxazolyl, oxadiazolyl, furazanyl, pyridyl, bipyridyl, pyridazinyl, pyrimidyl, pyrazinyl, triazinyl, tetrazinyl, benzofuranyl, benzothiophenyl, indolyl, isoindazolyl, benzimidazolyl, benzotriazolyl, benzoxazolyl, quinolyl, isoquinolyl, cinnolyl, quinazolyl, naphthyridyl, phthalazyl, phentriazyl, benzotetrazyl, carbazolyl, dibenzofuranyl, dibenzothiophenyl, acridyl, and phenazyl.

In some embodiments, Ar₁ and Ar₂ may be independently selected from the group consisting of: fluorenyl, terphenyl, tetraphenyl, pyrenyl, phenanthryl, pyrrolyl, furanyl, imidazolyl, triazolyl, isoxazolyl, oxadiazolyl, furazanyl, pyridazinyl, pyrimidyl, pyrazinyl, triazinyl, tetrazinyl, benzofuranyl, benzothiophenyl, indolyl, isoindazolyl, benzimidazolyl, benzotriazolyl, benzoxazolyl, quinolyl, isoquinolyl, cinnoiyl, quinazolyl, naphthyridyl, phthalazyl, phentriazyl, benzotetrazyl, carbazolyl, dibenzofuranyl, dibenzothiophenyl, acridyl, and phenazyl.

The aromatic moiety from which Ar₁ and Ar₂ are independently selected includes any of the above aromatic moieties that further comprise one or more substituents, as defined below, on one or more rings of the aromatic moiety. In some embodiments, the substituent may be a moiety selected from the aforementioned group of aromatic moieties.

As indicated above, L is a covalent bond or a chemical moiety. In some embodiments, L is a single bond or a chemical moiety that is a linking group, which in combination with certain atoms of one or more rings of Ar₁ and Ar₂ comprise a polymer backbone. The linking group may comprise 1 to about 100 atoms, or 1 to about 70 atoms, or 1 to 50 atoms, or 1 to 20 atoms, or 1 to about 10 atoms, or 2 to about 10 atoms, or 2 to about 20 atoms, or 3 to about 10 atoms, or about 3 to about 20 atoms, or 4 to about 10 atoms, or 4 to about 20 atoms, or 5 to about 10 atoms, or about 5 to about 20 atoms. The atoms are each independently selected from the group consisting of carbon, oxygen, sulfur, nitrogen, halogen and phosphorous. The number of heteroatoms in the linking group should not be such as to interfere with the hydrophobicity of a polymer-particle composition as discussed in more detail below. The number of heteroatoms in the linking group may range from 0 to about 20, or from 1 to about 15, or from 1 to about 6, or from 1 to about 5, or from 1 to about 4, or from 1 to about 3, or from 1 to 2, or from 0 to about 5, or from 0 to about 4, or from 0 to about 3, or from 0 to 2 or from 0 to 1. The length of a particular linking group can be selected to one or both of provide for convenience of synthesis and the incorporation of the desired aromatic Ar group into the polymer matrix and provide for sufficient binding of BG to a particle. The linking groups may be aliphatic or aromatic and may comprise, for example, alkylene, substituted alkylene, alkylenoxy, substituted alkylenoxy, thioalkylene, substituted thioalkylene, alkenylene, substituted alkenylene, alkenylenoxy, substituted alkenylenoxy, thioalkenylene, substituted thioalkenylene, alkynylene, substituted alkynylene, alkynylenoxy, substituted alkynylenoxy, thioalkynylene, substituted thioalkynylene, arylene, substituted arylene, arylenoxy, thioarylene, and counterparts thereof comprising one or more heteroatoms. The length of the linking group in some embodiments is about 2 to about 10 atoms, or about 2 to about 9 atoms, or about 2 to about 8 atoms, or about 2 to about 7 atoms, or about 2 to about 6 atoms, or about 2 to about 5 atoms, or about 2 to about 4 atoms. In some embodiments, L is not, or does not comprise, a carbon-carbon double bond or a carbon-carbon triple bond. In some embodiments, L is, or comprises, one or more of a carbon-carbon double bond, a carbon-carbon triple bond, a carbon-nitrogen double bond, and a nitrogen-nitrogen double bond, for example, which renders the resulting copolymer embodiment semi-conducting.

The composition and length of the linking group should be such as not to interfere with the binding of BG to a particle or with the functions of SG. The linking group should be hydrophobic to the extent that the homogeneity of mixtures of the particle in a non-polar medium is not compromised. Furthermore, the chemistry used to introduce the linking group should not be detrimental to the molecule in question. The linking group may be introduced into the monomeric unit by means of a functional group that covalently binds to a corresponding functional group on the monomeric unit. Such functional groups may be selected from the same functional groups as that for BG discussed below.

As mentioned above, Z₁ is a covalent bond or a chemical moiety providing a covalent bond between BG and Q₁. The chemical moiety may be aliphatic or aromatic and may be, for example, alkylene, substituted alkylene, alkylenoxy, substituted alkylenoxy, thioalkylene, substituted thioalkylene, alkenylene, substituted alkenylene, alkenylenoxy, substituted alkenylenoxy, thioalkenylene, substituted thioalkenylene, alkynylene, substituted alkynylene, alkynylenoxy, substituted alkynylenoxy, thioalkynylene, substituted thioalkynylene, arylene, substituted arylene, arylenoxy, thioarylene, and counterparts thereof comprising one or more heteroatoms, for example. The number of carbon atoms in any of the above groups may be 1 to about 30 or more, or 1 to about 25, or 1 to about 20, or 1 to about 15, or 1 to about 10, or 1 to about 5, or 2 to about 30 or more, or 2 to about 25, or 2 to about 20, or 2 to about 15, or 2 to about 10, or 2 to about 5, or 3 to about 30 or more, or 3 to about 25, or 3 to about 20, or 3 to about 15, or 3 to about 10, or 3 to about 5, or 5 to about 30 or more, or 5 to about 25, or 5 to about 20, or 5 to about 15, or 5 to about 10, for example.

Also as mentioned above, Z₂ is a covalent bond or a chemical moiety providing a covalent bond between SG and Q₂. The chemical moiety may be aliphatic or aromatic and may be, for example, alkylene, substituted alkylene, alkylenoxy, substituted alkylenoxy, thioalkylene, substituted thioalkylene, alkenylene, substituted alkenylene, alkenylenoxy, substituted alkenylenoxy, thioalkenylene, substituted thioalkenylene, alkynylene, substituted alkynylene, alkynylenoxy, substituted alkynylenoxy, thioalkynylene, substituted thioalkynylene, arylene, substituted arylene, arylenoxy, thioarylene, and counterparts thereof comprising one or more heteroatoms, for example. The number of carbon atoms in any of the above groups may be 1 to about 30 or more, or 1 to about 25, or 1 to about 20, or 1 to about 15, or 1 to about 10, or 1 to about 5, or 2 to about 30 or more, or 2 to about 25, or 2 to about 20, or 2 to about 15, or 2 to about 10, or 2 to about 5, or 3 to about 30 or more, or 3 to about 25, or 3 to about 20, or 3 to about 15, or 3 to about 10, or 3 to about 5, or 5 to about 30 or more, or 5 to about 25, or 5 to about 20, or 5 to about 15, or 5 to about 10, for example.

As indicated above, the function of BG is to bind to a particle. BG may be any functional group or structure that can either coordinate with or form a covalent bond with a particle so as to be chemically attached to the particle. The nature of BG is dependent on the nature and chemical composition of the particle, the size of the particle, any surface treatment of the particle, and so forth. As mentioned above, BG may bind to a particle by a covalent bond or by a coordination bond (chemical complex). A covalent bond is characterized by the sharing of electrons, usually pairs of electrons, between atoms or between atoms and other covalent bonds. A coordination bond is characterized by the donation of electrons from a lone electron pair into an empty orbital of a metal, for example. The electron donor is referred to as a ligand and the resulting complex is referred to as a coordination compound. Accordingly, BG may bind to the particle by means of ligand exchange or covalent bonding.

By way of example and not limitation, the functional group may include at least one electron donating group (which may be electrically neutral or negatively charged). Electron donating groups often include atoms such as O, N, S, and P as well as combination thereof, for example, P═O groups, and S═O groups. By way of example and not limitation, the binding group BG may include a primary, secondary or tertiary amine or amide group, a nitrile group, an isonitrile group, a cyanate group, an isocyanate group, a thiocyanate group, an isothiocyanate group, an azide group, a thio group, a thiolate group, a sulfide group, a sulfinate group, a sulfonate group, a phosphate group, a hydroxyl group, an alcoholate group, a phenolate group, a carbonyl group, a carboxylate group, a phosphine group, a phosphine oxide group, a phosphonic acid group, a phosphoramide group, a phosphate group, a phosphite group, as well as combinations and mixtures of such groups.

One of the aforementioned functional groups may react with a corresponding functional group on a particle, that is present on the particle or introduced on the surface of the particle. In one embodiment, ligands can be provided and chemically attached to the particle. The ligands may include a binding group that is configured to form a chemical bond or a chemical complex with a particle. The ligands may also include a functional group that is configured to react with BG, which is a complementary functional group. The particles having the ligands bound thereto then may be mixed with the molecules of the polymer, and the complementary functional groups react with one another to form a covalently bonded link.

Examples of ligands, by way of illustration and not limitation, include difunctional ligands such as amino acids, for example, alanine, cysteine, and glycine, for example; aminoaliphatic acids, aminoaromatic acids, aminoaliphatic thiols, aminoaromatic thiols, for example.

By way of illustration and not limitation, one of BG or the functional group on the particle may include a nucleophile (such as, for example, amines, alcohols, and thiols), and the other of BG or the functional group on the particle may include a functional group capable of reacting with a nucleophile (such as, for example, aldehydes, isocyanates, isothiocyanates, succinimidyl esters, sulfonyl chlorides, epoxides, bromides, chlorides, iodides, and maleimides). Examples, by way of illustration and not limitation, of the reaction products of corresponding functionalities of BG and the particle include amides, amidines and phosphoramides, respectively, from a reaction of amine and carboxylic acid or its nitrogen derivative or phosphoric acid (including esters thereof such as, for example, a succinimidyl ester); thioethers from a reaction of a mercaptan and an activated olefin or a mercaptan and an alkylating agent; alkylamine from a reaction of an aldehyde and an amine under reducing conditions; esters from a reaction of a carboxylic acid or phosphate acid and an alcohol; and imines from a reaction of an amine and an aldehyde.

As mentioned above, SG is a hydrophobic moiety that provides for steric stabilization and homogeneity of mixtures of the nanoparticle in a non-polar medium. For the most part, SG is hydrophobic and is sterically bulky. The degree of hydrophobicity of SG is that sufficient to enhance the homogeneity of particles, to which the polymer is bound, in a non-polar medium. The degree of hydrophobicity is dependent on the nature of the non-polar medium, and the nature of SG, for example. Steric stabilization of the particles means that the ability of the particles to stick together or coagulate is substantially reduced or eliminated particularly when the particles are in a non-polar medium. As a result, the homogeneity of a mixture of the particles in a non-polar medium is enhanced as discussed more fully below. The phrase “mixture of particles in a non-polar medium” refers to particles of the same composition, or particles of more than one composition, i.e., two or more different particles, mixed with a non-polar medium. The term “hydrophobic” or “hydrophobicity” refers to a molecule that is non-polar and thus prefers neutral molecules or non-polar molecules and prefers non-polar solvents. Hydrophobic molecules have an affinity for other hydrophobic moieties compared to hydrophilic moieties.

The functionalized polymer-nanoparticle compositions in accordance with the present embodiments form homogeneous mixtures in a non-polar medium by virtue of the hydrophobic nature of the SG moiety. In the context of the present embodiments, the homogeneity of the mixture in the non-polar medium may be actual or apparent. The homogeneity of the mixture in the non-polar medium is actual when the polymer-particle composition is soluble in the non-polar medium, which means that the polymer-particle composition exhibits a certain amount, usually a maximum amount, of solubility in a certain volume of solvent at a specified temperature. The homogeneity of the mixture of the polymer-particle composition in a non-polar medium is apparent when the polymer-particle composition is dispersed in the non-polar medium such that the mixture exhibits apparent homogeneity but the mixture is microscopically heterogeneous. Apparent homogeneity may also be referred to as a dispersion. Whether the homogeneity of the mixture of the polymer-particle composition is actual or apparent is dependent on the nature of the particle, and the nature of the non-polar medium, for example. Steric stabilization of the particles, which results from the hydrophobicity of SG in the present embodiments, reduces the ability of the particles to stick together in a non-polar medium, thus providing enhanced homogeneity and stability of nanoparticle colloids. The present functionalized polymers render the functionalized polymer-particle compositions compatible with a non-polar medium.

The phrase “non-polar medium” means that the medium is primarily hydrocarbon in nature and is comprised of non-polar molecules, i.e., molecules with little or no net electric dipole moment. The medium is preferably environmentally compatible or friendly having little or no toxicity. Examples of non-polar media, by way of illustration and not limitation, include, for example, hydrocarbons containing 1 to about 30 carbon atoms, or 1 to about 20 carbon atoms, or 1 to about 10 carbon atoms, or 5 to about 30 carbon atoms, or 5 to about 20 carbon atoms, or 5 to about 10 carbon atoms, or to about 30 carbon atoms, or 10 to about 20 carbon atoms, for example. The hydrocarbon may comprise one or more heteroatoms such as, for example, oxygen, nitrogen, and sulfur, provided that the presence of the heteroatoms does not significantly alter the hydrophobicity and environmental compatibility of the medium. The hydrocarbon may comprise atoms other than heteroatoms such as halogens or halo substituents, for example provided that the presence of the heteroatoms does not significantly alter the hydrophobicity and environmental compatibility of the medium.

As mentioned above, SG is also a sterically bulky group that provides stability to a polymer-particle composition. The term “stability” refers to the ability of polymer-nanoparticle compositions in accordance with the present embodiments to remain in the non-polar medium for an extended period such as, for example, about 1 to about 1,000 hours, or about 1 to about 500 hours, or about 1 to about 400 hours, or about 1 to about 300 hours, or about 1 to about 200 hours, or about 1 to about 100 hours, or about 1 to about 50 hours, or about 1 to about 25 hours, or about 5 to about 1,000 hours, or about 5 to about 500 hours, or about 5 to about 400 hours, or about 5 to about 300 hours, or about 5 to about 200 hours, or about 5 to about 100 hours, or about 5 to about 50 hours, or about 5 to about 25 hours, without one or both of aggregating in and precipitating out from the solution. SG is alkyl, substituted alkyl, heteroalkyl (e.g., alkoxy, substituted alkoxy, thioalkyl, substituted thioalkyl), alkenyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl). In some embodiments, the combined number of carbon atoms in SG, Z₂ and Q₂ is at least 10, or at least 15, or at least 20, or at least 25, or at least 30, or at least 35, or at least 40, or at least 45, or at least 50, or at least 55, or at least 60, for example.

In some embodiments, SG is about 5 to about 50 carbon atoms, or about 5 to about 45 carbon atoms, or about 5 to about 40 carbon atoms, or about 5 to about 35 carbon atoms, or about 5 to about 30 carbon atoms, or about 5 to about 25 carbon atoms, or about 5 to about 20 carbon atoms, or about 5 to about 15 carbon atoms, or about 5 to about 10 carbon atoms, or about 10 to about 50 carbon atoms, or about 10 to about 45 carbon atoms, or about 10 to about 40 carbon atoms, or about 10 to about 35 carbon atoms, or about 10 to about 30 carbon atoms, or about 10 to about 25 carbon atoms, or about 10 to about 20 carbon atoms, or about 10 to about 15 carbon atoms, or about 15 to about 50 carbon, or about 15 to about 45 carbon atoms, or about 15 to about 40 carbon atoms, or about 15 to about 35 carbon atoms, or about 15 to about 30 carbon atoms, or about 15 to about 25 carbon atoms, or about 15 to about 20 carbon atoms, or about 20 to about 50 carbon atoms, or about 20 to about 45 carbon atoms, or about 20 to about 40 carbon atoms, or about 20 to about 35 carbon atoms, or about 20 to about 30 carbon atoms, or about 20 to about 25 carbon atoms, or about 25 to about 50 carbon atoms, or about 25 to about 45 carbon atoms, or about 25 to about 40 carbon atoms, or about 25 to about 35 carbon atoms, or about 25 to about 30 carbon atoms, or about 30 to about 50 carbon atoms, or about 30 to about 45 carbon atoms, or about 30 to about 40 carbon atoms, or about 30 to about 35 carbon atoms, or about 35 to about 50 carbon atoms, or about 35 to about 45 carbon atoms, or about 35 to about 40 carbon atoms, for example.

In some embodiments, wherein SG is branched, the number of atoms in a chain is about 5 to about 50 carbon atoms, or about 5 to about 45 carbon atoms, or about 5 to about 40 carbon atoms, or about 5 to about 35 carbon atoms, or about 5 to about 30 carbon atoms, or about 5 to about 25 carbon atoms, or about 5 to about 20 carbon atoms, or about 5 to about 15 carbon atoms, or about 5 to about 10 carbon atoms, or about 10 to about 50 carbon atoms, or about 10 to about 45 carbon atoms, or about 10 to about 40 carbon atoms, or about 10 to about 35 carbon atoms, or about 10 to about 30 carbon atoms, or about 10 to about 25 carbon atoms, or about 10 to about 20 carbon atoms, or about 10 to about 15 carbon atoms, or about 15 to about 50 carbon, or about 15 to about 45 carbon atoms, or about 15 to about 40 carbon atoms, or about 15 to about 35 carbon atoms, or about 15 to about 30 carbon atoms, or about 15 to about 25 carbon atoms, or about 15 to about 20 carbon atoms, or about 20 to about 50 carbon atoms, or about 20 to about 45 carbon atoms, or about 20 to about 40 carbon atoms, or about 20 to about 35 carbon atoms, or about 20 to about 30 carbon atoms, or about 20 to about 25 carbon atoms, or about 25 to about 50 carbon atoms, or about 25 to about 45 carbon atoms, or about 25 to about 40 carbon atoms, or about 25 to about 35 carbon atoms, or about 25 to about 30 carbon atoms, or about 30 to about 50 carbon atoms, or about 30 to about 45 carbon atoms, or about 30 to about 40 carbon atoms, or about 30 to about 35 carbon atoms, or about 35 to about 50 carbon atoms, or about 35 to about 45 carbon atoms, or about 35 to about 40 carbon atoms, for example, and the total number of carbon atoms may be more than about 50, or more than about 55, or more than about 60, for example, or about 20 to about 55, or about 20 to about 60, or about 20 to about 65, for example.

In some embodiments, m and n are integers independently between 1 and about 5,000, or between 1 and about 4000, or between 1 and about 3000, or between 1 and about 2000, or between 1 and about 1000, or between 1 and about 500, or between 1 and about 100, between 2 and about 5,000, or between 2 and about 4000, or between 2 and about 3000, or between 2 and about 2000, or between 2 and about 1000, or between 2 and about 500, or between 2 and about 100, or between 3 and about 5,000, or between 3 and about 4000, or between 3 and about 3000, or between 3 and about 2000, or between 3 and about 1000, or between 3 and about 500, or between 3 and about 100, or between 4 and about 5,000, or between 4 and about 4000, or between 4 and about 3000, or between 4 and about 2000, or between 4 and about 1000, or between 4 and about 500, or between 4 and about 100, or between 5 and about 4000, or between 5 and about 3000, or between 5 and about 2000, or between 5 and about 1000, or between 5 and about 500, or between 5 and about 100, or between 10 and about 4000, or between 10 and about 3000, or between 10 and about 2000, or between 10 and about 1000, or between 10 and about 500, or between 10 and about 100, or between 20 and about 4000, or between 20 and about 3000, or between 20 and about 2000, or between 20 and about 1000, or between 20 and about 500, or between 20 and about 100, or between 50 and about 4000, or between 50 and about 3000, or between 50 and about 2000, or between 50 and about 1000, or between 50 and about 500, or between 50 and about 100, or between 100 and about 4000, or between 100 and about 3000, or between 100 and about 2000, or between 100 and about 1000, or between 100 and about 500, or between 200 and about 4000, or between 200 and about 3000, or between 200 and about 2000, or between 200 and about 1000, or between 200 and about 500, or between 500 and about 4000, or between 500 and about 3000, or between 500 and about 2000, or between 500 and about 1000, or between 1000 and about 4000, or between 1000 and about 3000, or between 1000 and about 2000, for example. In some embodiments, m and n are both even numbers. In some embodiments, m and n are odd numbers. In some embodiments, one of m or n is an even number and the other is an odd number. In some embodiments, m and n may vary from one co-block to another co-block within the same block copolymer. By the phrase ‘co-block’ is meant the two blocks that comprise each repeating unit when v is greater than 1.

In some embodiments the value of m and n is controlled during the preparation of the functionalized polymer. The molar concentration of the monomer units that are employed in the preparation of the polymer may be selected to determine the value of m and n. Thus, the number of the binding groups BG and the number of stability enhancing and homogeneity enhancing groups SG are controlled in the final functionalized polymer. The polymer may be tailored to the particular nanoparticle, its composition and its use.

In some embodiments, the ratio of m:n is in a range of about 1:100 to about 100:1, or about 1:90 to about 90:1, or about 1:80 to about 80:1, or about 1:70 to about 70:1, or about 1:60 to about 60:1, or about 1:50 to about 50:1, or about 1:40 to about 40:1, or about 1:30 to about 30:1, or about 1:20 to about 20:1, or about 1:10 to about 10:1, or about 1:50 to about 1:1, or about 1:40 to about 1:1, or about 1:30 to about 1:1, or about 1:20 to about 1:1, or about 1:10 to about 1:1, or about 1:5 to about 1:1, or about 1:50 to about 1:2, or about 1:40 to about 1:2, or about 1:30 to about 1:2, or about 1:20 to about 1:2, or about 1:10 to about 1:2, or about 1:5 to about 1:2, or about 1:50 to about 1:3, or about 1:40 to about 1:3, or about 1:30 to about 1:3, or about 1:20 to about 1:3, or about 1:10 to about 1:3, or about 1:5 to about 1:3, or about 1:50 to about 1:4, or about 1:40 to about 1:4, or about 1:30 to about 1:4, or about 1:20 to about 1:4, or about 1:10 to about 1:4, or about 1:5 to about 1:4, or about 1:50 to about 1:5, or about 1:40 to about 1:5, or about 1:30 to about 1:5, or about 1:20 to about 1:5 or about 1:10 to about 1:5, for example.

In some embodiments, the ratio of m:n is about 1:100, or about 1:90, or about 1:80, or about 1:70, or about 1:60, or about 1:50, or about 1:40, or about 1:30, or about 1:20, or about 1:10, or about 1:5, or about 1:4, or about 1:3, or about 1:2, or about 1:1, or about 100:1, or about 90:1, or about 80:1, or about 70:1, or about 60:1, or about 50:1, or about 40:1, or about 30:1, or about 20:1, or about 10:1, or about 5:1, or about 4:1, or about 3:1, or about 2:1, for example.

In some embodiments, v is an integer greater than about 10, or greater than about 20, or greater than about 30, or greater than about 40, or greater than about 50, or greater than about 100, or greater than about 200, or greater than about 300, or greater than about 400, or greater than about 500, or greater than about 1000, greater than about 2000, or greater than about 3000, or greater than about 4000, or greater than about 5000, or greater than about 10,000, for example.

In some embodiments, the functionalized polymer comprises two blocks wherein each block comprises repeating monomer units; such functionalized polymer has the formula:

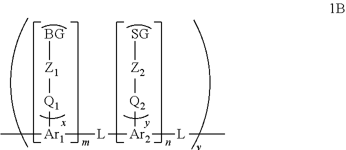

wherein:

BG is selected from the group consisting of primary amines, secondary amines, tertiary amines, amides, nitriles, isonitriles, cyanates, isocyanates, thiocyanates, isothiocyanates, azides, thiols, thiolates, sulfides, sulfinates, sulfonates, phosphates, hydroxyls, alcoholates, phenolates, carbonyls, carboxylates, phosphines, phosphine oxides, phosphonic acids, phosphoramides and phosphates,

Z₁ provides a covalent bond between BG and Q₁, and is independently selected from the group consisting of a covalent bond and a chemical moiety selected from the group consisting of alkylene of 1 to about 30 carbon atoms, substituted alkylene of 1 to about 30 carbon atoms, alkylenoxy of 1 to about 30 carbon atoms, substituted alkylenoxy of 1 to about 30 carbon atoms, thioalkylene of 1 to about 30 carbon atoms, substituted thioalkylene of 1 to about 30 carbon atoms, alkenylene of 1 to about 30 carbon atoms, substituted alkenylene of 1 to about 30 carbon atoms, alkenylenoxy of 1 to about 30 carbon atoms, substituted alkenylenoxy of 1 to about 30 carbon atoms, thioalkenylene of 1 to about 30 carbon atoms, substituted thioalkenylene of 1 to about 30 carbon atoms, alkynylene of 1 to about 30 carbon atoms, substituted alkynylene of 1 to about 30 carbon atoms, alkynylenoxy of 1 to about 30 carbon atoms, substituted alkynylenoxy of 1 to about 30 carbon atoms, thioalkynylene of 1 to about 30 carbon atoms, substituted thioalkynylene of 1 to about 30 carbon atoms, arylene of 1 to about 30 carbon atoms, substituted arylene of 1 to about 30 carbon atoms, arylenoxy of 1 to about 30 carbon atoms, thioarylene of 1 to about 30 carbon atoms, and counterparts of the above comprising one or more heteroatoms; or in some embodiments, the chemical moiety is selected from the group consisting of alkylene of 1 to 30 carbon atoms, arylene of 1 to 30 carbon atoms, substituted alkylene of 1 to 30 carbon atoms, substituted arylene of 1 to 30 carbon atoms, arylenoxy of 1 to about 30 carbon atoms, thioarylene of about 1 to about 30 carbon atoms, substituted arylenoxy of 1 to about 30 carbon atoms, substituted thioarylene of about 1 to about 30 carbon atoms, and counterparts of the above comprising one or more heteroatoms, providing a covalent bond between BG and Q₁,

Z₂ provides a covalent bond between SG and Q₂, and is independently selected from the group consisting of a covalent bond and a chemical moiety selected from the group consisting of alkylene of 1 to about 30 carbon atoms, substituted alkylene of 1 to about 30 carbon atoms, alkylenoxy of 1 to about 30 carbon atoms, substituted alkylenoxy of 1 to about 30 carbon atoms, thioalkylene of 1 to about 30 carbon atoms, substituted thioalkylene of 1 to about 30 carbon atoms, alkenylene of 1 to about 30 carbon atoms, substituted alkenylene of 1 to about 30 carbon atoms, alkenylenoxy of 1 to about 30 carbon atoms, substituted alkenylenoxy of 1 to about 30 carbon atoms, thioalkenylene of 1 to about 30 carbon atoms, substituted thioalkenylene of 1 to about 30 carbon atoms, alkynylene of 1 to about 30 carbon atoms, substituted alkynylene of 1 to about 30 carbon atoms, alkynylenoxy of 1 to about 30 carbon atoms, substituted alkynylenoxy of 1 to about 30 carbon atoms, thioalkynylene of 1 to about 30 carbon atoms, substituted thioalkynylene of 1 to about 30 carbon atoms, arylene of 1 to about 30 carbon atoms, substituted arylene of 1 to about 30 carbon atoms, arylenoxy of 1 to about 30 carbon atoms, thioarylene of 1 to about 30 carbon atoms, and counterparts of the above comprising one or more heteroatoms; or in some embodiments, the chemical moiety is selected from the group consisting of alkylene of 1 to 30 carbon atoms, arylene of 1 to 30 carbon atoms, substituted alkylene of 1 to 30 carbon atoms, substituted arylene of 1 to 30 carbon atoms, arylenoxy of 1 to about 30 carbon atoms, thioarylene of about 1 to about 30 carbon atoms, substituted arylenoxy of 1 to about 30 carbon atoms, substituted thioarylene of about 1 to about 30 carbon atoms, and counterparts of the above comprising one or more heteroatoms, providing a covalent bond between SG and Q₂,

Q₁ is a carbon atom or a heteroatom,

Q₂ is a carbon atom or a heteroatom,

Ar₁ and Ar₂ are each independently selected from the group consisting of phenyl, fluorenyl, biphenyl, terphenyl, tetraphenyl, naphthyl, anthryl, pyrenyl, phenanthryl, thiophenyl, pyrrolyl, furanyl, imidazolyl, triazolyl, isoxazolyl, oxazolyl, oxadiazolyl, furazanyl, pyridyl, bipyridyl, pyridazinyl, pyrimidyl, pyrazinyl, triazinyl, tetrazinyl, benzofuranyl, benzothiophenyl, indolyl, isoindazolyl, benzimidazolyl, benzotriazolyl, benzoxazolyl, quinolyl, isoquinolyl, cinnolyl, quinazolyl, naphthyridyl, phthalazyl, phentriazyl, benzotetrazyl, carbazolyl, dibenzofuranyl, dibenzothiophenyl, acridyl, and phenazyl; in some embodiments, Ar₁ and Ar₂ are each selected from the group consisting of fluorenyl, for example,

L is independently a covalent bond directly linking Ar₁ and Ar₂ or a linking group selected from the group consisting of:

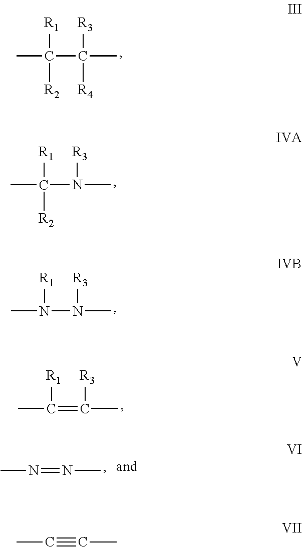

wherein:

R₁, R₂, R₃, R₄ are each independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl),

m and n are integers independently between 2 and about 5,000,

v is an integer greater than about 10,

x and y are integers independently between 1 and about 5, or between 1 and about 4, or between 1 and about 3, or between 1 and 2, or between 2 and about 5, or between 2 and about 4, or between 2 and about 3, between 3 and about 5, or between 3 and about 4, or between 4 and about 5,

SG is selected from the group consisting of alkyl of about 5 to about 50 carbon atoms, substituted alkyl of about 5 to about 50 carbon atoms, alkoxy of about 5 to about 50 carbon atoms, substituted alkoxy of about 5 to about 50 carbon atoms, thioalkyl of about 5 to about 50 carbon atoms, substituted thioalkyl of about 5 to about 50 carbon atoms, alkenyl of about 5 to about 50 carbon atoms, substituted alkenyl of about 5 to about 50 carbon atoms, alkenoxy of about 5 to about 50 carbon atoms, substituted alkenoxy of about 5 to about 50 carbon atoms, thioalkenyl of about 5 to about 50 carbon atoms, substituted thioalkenyl of about 5 to about 50 carbon atoms, alkynyl of about 5 to about 50 carbon atoms, substituted alkynyl of about 5 to about 50 carbon atoms, alkynoxy of about 5 to about 50 carbon atoms, substituted alkynoxy of about 5 to about 50 carbon atoms, thioalkynyl of about 5 to about 50 carbon atoms, substituted thioalkynyl of about 5 to about 50 carbon atoms, aryl of about 5 to about 50 carbon atoms, substituted aryl of about 5 to about 50 carbon atoms, aryloxy of about 5 to about 50 carbon atoms, substituted aryloxy of about 5 to about 50 carbon atoms, thioaryl of about 5 to about 50 carbon atoms, substituted thioaryl of about 5 to about 50 carbon atoms and including counterparts thereof comprising one or more heteroatoms; in some embodiments SG is selected from the group consisting of alkyl of about 5 to about 50 carbon atoms, alkoxy of about 5 to about 50 carbon atoms, aryl of about 5 to about 50 carbon atoms, aryloxy of about 5 to about 50 carbon atoms, alkylaryl of about 5 to about 50 carbon atoms, thioaryl of about 5 to about 50 carbon atoms, and including substituted counterparts thereof.

In some embodiments, the functionalized polymer comprises repeating monomer units and has the formula:

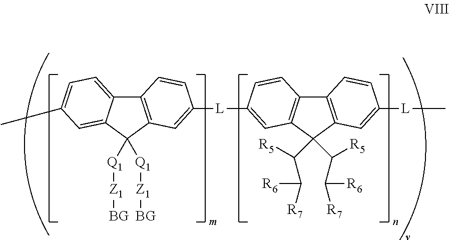

wherein:

BG is independently selected from the group consisting of primary amines, secondary amines, tertiary amines, amides, nitriles, isonitriles, cyanates, isocyanates, thiocyanates, isothiocyanates, azides, thiols, thiolates, sulfides, sulfinates, sulfonates, phosphates, hydroxyls, alcoholates, phenolates, carbonyls, carboxylates, phosphines, phosphine oxides, phosphonic acids, phosphoramides and phosphates,

Z₁ is independently selected from the group consisting of a covalent bond and a chemical moiety selected from the group consisting of alkylene of 1 to about 30 carbon atoms, substituted alkylene of 1 to about 30 carbon atoms, alkylenoxy of 1 to about 30 carbon atoms, substituted alkylenoxy of 1 to about 30 carbon atoms, thioalkylene of 1 to about 30 carbon atoms, substituted thioalkylene of 1 to about 30 carbon atoms, alkenylene of 1 to about 30 carbon atoms, substituted alkenylene of 1 to about 30 carbon atoms, alkenylenoxy of 1 to about 30 carbon atoms, substituted alkenylenoxy of 1 to about 30 carbon atoms, thioalkenylene of 1 to about 30 carbon atoms, substituted thioalkenylene of 1 to about 30 carbon atoms, alkynylene of 1 to about 30 carbon atoms, substituted alkynylene of 1 to about 30 carbon atoms, alkynylenoxy of 1 to about 30 carbon atoms, substituted alkynylenoxy of 1 to about 30 carbon atoms, thioalkynylene of 1 to about 30 carbon atoms, substituted thioalkynylene of 1 to about 30 carbon atoms, arylene of 1 to about 30 carbon atoms, substituted arylene of 1 to about 30 carbon atoms, arylenoxy of 1 to about 30 carbon atoms, thioarylene of 1 to about 30 carbon atoms, and counterparts of the above comprising one or more heteroatoms; or in some embodiments, the chemical moiety is selected from the group consisting of alkylene of 1 to 30 carbon atoms, arylene of 1 to 30 carbon atoms, substituted alkylene of 1 to 30 carbon atoms, substituted arylene of 1 to 30 carbon atoms, arylenoxy of 1 to about 30 carbon atoms, thioarylene of about 1 to about 30 carbon atoms, substituted arylenoxy of 1 to about 30 carbon atoms, substituted thioarylene of about 1 to about 30 carbon atoms, and counterparts of the above comprising one or more heteroatoms, providing a covalent bond between BG and Q₁,

Q₁ is a carbon atom or a heteroatom,

L is independently a covalent bond or a linking group selected from the group consisting of:

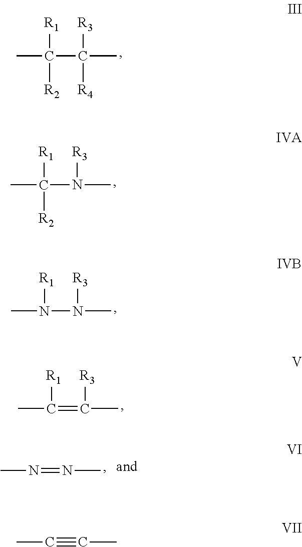

wherein R₁, R₂, R₃, R₄ are each independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl),

m and n are integers independently between 1 and about 5,000; in some embodiments, m and n are at least 2, in some embodiments the molar concentration of the starting monomers may be adjusted to adjust the value of m and n in the resulting polymer and adjust the value of m and n in each of the co-blocks that comprise each v; for example, m can be 1 and n can be 5 in one co-block and m can be 1 and n can be 6 in another co-block,

v is an integer greater than about 10,

each R₅ is independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl),

each R₆ is independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl), and

each R₇ is independently selected from the group consisting of alkyl of about 5 to about 50 carbon atoms, substituted alkyl of about 5 to about 50 carbon atoms, alkenyl of about 5 to about 50 carbon atoms, substituted alkenyl of about 5 to about 50 carbon atoms, alkynyl of about 5 to about 50 carbon atoms, substituted alkynyl of about 5 to about 50 carbon atoms, alkoxy of about 5 to about 50 carbon atoms, substituted alkoxy of about 5 to about 50 carbon atoms, alkenoxy of about 5 to about 50 carbon atoms, substituted alkenoxy of about 5 to about 50 carbon atoms, alkynoxy of about 5 to about 50 carbon atoms, substituted alkynoxy of about 5 to about 50 carbon atoms, thioalkyl of about 5 to about 50 carbon atoms, substituted thioalkyl of about 5 to about 50 carbon atoms, aryl of about 5 to about 50 carbon atoms, aryloxy of about 5 to about 50 carbon atoms, thioaryl of about 5 to about 50 carbon atoms, alkylaryl of about 5 to about 50 carbon atoms, and corresponding substituted moieties thereof; in some embodiments, each R₇ is independently selected from the group consisting alkyl of about 10 to about 50 carbon atoms, substituted alkyl of about 10 to about 50 carbon atoms, alkenyl of about 10 to about 50 carbon atoms, substituted alkenyl of about 10 to about 50 carbon atoms, alkynyl of about 10 to about 50 carbon atoms, substituted alkynyl of about 10 to about 50 carbon atoms, alkoxy of about 10 to about 50 carbon atoms, substituted alkoxy of about 10 to about 50 carbon atoms, alkenoxy of about 10 to about 50 carbon atoms, substituted alkenoxy of about 10 to about 50 carbon atoms, alkynoxy of about 10 to about 50 carbon atoms, substituted alkynoxy of about 10 to about 50 carbon atoms, thioalkyl of about 10 to about 50 carbon atoms, substituted thioalkyl of about 10 to about 50 carbon atoms, aryl of about 10 to about 50 carbon atoms, aryloxy of about 10 to about 50 carbon atoms, thioaryl of about 10 to about 50 carbon atoms, alkylaryl of about 10 to about 50 carbon atoms, and corresponding substituted moieties thereof; in some embodiments, each R₇ is independently selected from the group consisting of alkyl of about 5 to about 40 carbon atoms, substituted alkyl of about 5 to about 40 carbon atoms, alkenyl of about 5 to about 40 carbon atoms, substituted alkenyl of about 5 to about 40 carbon atoms, alkynyl of about 5 to about 40 carbon atoms, substituted alkynyl of about 5 to about 40 carbon atoms, alkoxy of about 5 to about 40 carbon atoms, substituted alkoxy of about 5 to about 40 carbon atoms, alkenoxy of about 5 to about 40 carbon atoms, substituted alkenoxy of about 5 to about 40 carbon atoms, alkynoxy of about 5 to about 40 carbon atoms, substituted alkynoxy of about 5 to about 40 carbon atoms, thioalkyl of about 5 to about 40 carbon atoms, substituted thioalkyl of about 5 to about 40 carbon atoms, aryl of about 5 to about 40 carbon atoms, aryloxy of about 5 to about 40 carbon atoms, thioaryl of about 5 to about 40 carbon atoms, alkylaryl of about 5 to about 40 carbon atoms, and corresponding substituted moieties thereof; in some embodiments, each R₇ is independently selected from the group consisting of alkyl of about 15 to about 50 carbon atoms, substituted alkyl of about 15 to about 50 carbon atoms, alkenyl of about 15 to about 50 carbon atoms, substituted alkenyl of about 15 to about 50 carbon atoms, alkynyl of about 15 to about 50 carbon atoms, substituted alkynyl of about 15 to about 50 carbon atoms, alkoxy of about 15 to about 50 carbon atoms, substituted alkoxy of about 15 to about 50 carbon atoms, alkenoxy of about 15 to about 50 carbon atoms, substituted alkenoxy of about 15 to about 50 carbon atoms, alkynoxy of about 15 to about 50 carbon atoms, substituted alkynoxy of about 15 to about 50 carbon atoms, thioalkyl of about 15 to about 50 carbon atoms, substituted thioalkyl of about 15 to about 50 carbon atoms, aryl of about 15 to about 50 carbon atoms, aryloxy of about 15 to about 50 carbon atoms, thioaryl of about 15 to about 50 carbon atoms, alkylaryl of about 15 to about 50 carbon atoms, and corresponding substituted moieties thereof; in some embodiments, each R₇ is independently selected from the group consisting of alkyl of about 20 to about 50 carbon atoms, substituted alkyl of about 20 to about 50 carbon atoms, alkenyl of about 20 to about 50 carbon atoms, substituted alkenyl of about 20 to about 50 carbon atoms, alkynyl of about 20 to about 50 carbon atoms, substituted alkynyl of about 20 to about 50 carbon atoms, alkoxy of about 20 to about 50 carbon atoms, substituted alkoxy of about 20 to about 50 carbon atoms, alkenoxy of about 20 to about 50 carbon atoms, substituted alkenoxy of about 20 to about 50 carbon atoms, alkynoxy of about 20 to about 50 carbon atoms, substituted alkynoxy of about 20 to about 50 carbon atoms, thioalkyl of about 20 to about 50 carbon atoms, substituted thioalkyl of about 20 to about 50 carbon atoms, aryl of about 20 to about 50 carbon atoms, aryloxy of about 20 to about 50 carbon atoms, thioaryl of about 20 to about 50 carbon atoms, alkylaryl of about 20 to about 50 carbon atoms, and corresponding substituted moieties thereof; in some embodiments, the total number of carbon atoms in R₅, R₆ and R₇ is at least 10, or at least 15, or at least 20, or at least 25, or at least 30, for example, with the proviso that, if m is 1, at least one R₇ comprises at least 25 carbon atoms.

In some embodiments, the functionalized polymer comprises two blocks wherein each block comprises repeating monomer units; such functionalized polymer has the formula:

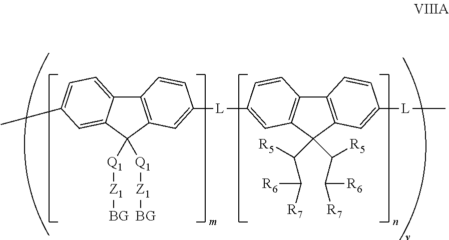

wherein:

BG is independently selected from the group consisting of primary amines, secondary amines, tertiary amines, amides, nitriles, isonitriles, cyanates, isocyanates, thiocyanates, isothiocyanates, azides, thiols, thiolates, sulfides, sulfinates, sulfonates, phosphates, hydroxyls, alcoholates, phenolates, carbonyls, carboxylates, phosphines, phosphine oxides, phosphonic acids, phosphoramides and phosphates,

Z₁ is independently selected from the group consisting of a covalent bond and a chemical moiety selected from the group consisting of alkylene of 1 to about 30 carbon atoms, substituted alkylene of 1 to about 30 carbon atoms, alkylenoxy of 1 to about 30 carbon atoms, substituted alkylenoxy of 1 to about 30 carbon atoms, thioalkylene of 1 to about 30 carbon atoms, substituted thioalkylene of 1 to about 30 carbon atoms, alkenylene of 1 to about 30 carbon atoms, substituted alkenylene of 1 to about 30 carbon atoms, alkenylenoxy of 1 to about 30 carbon atoms, substituted alkenylenoxy of 1 to about 30 carbon atoms, thioalkenylene of 1 to about 30 carbon atoms, substituted thioalkenylene of 1 to about 30 carbon atoms, alkynylene of 1 to about 30 carbon atoms, substituted alkynylene of 1 to about 30 carbon atoms, alkynylenoxy of 1 to about 30 carbon atoms, substituted alkynylenoxy of 1 to about 30 carbon atoms, thioalkynylene of 1 to about 30 carbon atoms, substituted thioalkynylene of 1 to about 30 carbon atoms, arylene of 1 to about 30 carbon atoms, substituted arylene of 1 to about 30 carbon atoms, arylenoxy of 1 to about 30 carbon atoms, thioarylene of 1 to about 30 carbon atoms, and counterparts of the above comprising one or more heteroatoms; or in some embodiments, the chemical moiety is selected from the group consisting of alkylene of 1 to 30 carbon atoms, arylene of 1 to 30 carbon atoms, substituted alkylene of 1 to 30 carbon atoms, substituted arylene of 1 to 30 carbon atoms, arylenoxy of 1 to about 30 carbon atoms, thioarylene of about 1 to about 30 carbon atoms, substituted arylenoxy of 1 to about 30 carbon atoms, substituted thioarylene of about 1 to about 30 carbon atoms, and counterparts of the above comprising one or more heteroatoms, providing a covalent bond between BG and Q₁,

Q₁ is a carbon atom or a heteroatom,

L is independently a covalent bond or a linking group selected from the group consisting of:

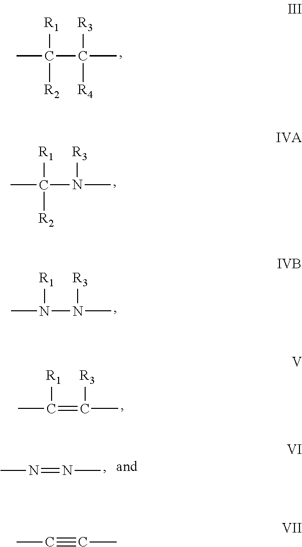

wherein R₁, R₂, R₃, R₄ are each independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl),

m and n are integers independently between 2 and about 5,000,

v is an integer greater than about 10,

each R5 is independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl),

each R6 is independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl), and

each R₇ is independently selected from the group consisting of alkyl of about 5 to about 50 carbon atoms, substituted alkyl of about 5 to about 50 carbon atoms, alkenyl of about 5 to about 50 carbon atoms, substituted alkenyl of about 5 to about 50 carbon atoms, alkynyl of about 5 to about 50 carbon atoms, substituted alkynyl of about 5 to about 50 carbon atoms, alkoxy of about 5 to about 50 carbon atoms, substituted alkoxy of about 5 to about 50 carbon atoms, alkenoxy of about 5 to about 50 carbon atoms, substituted alkenoxy of about 5 to about 50 carbon atoms, alkynoxy of about 5 to about 50 carbon atoms, substituted alkynoxy of about 5 to about 50 carbon atoms, thioalkyl of about 5 to about 50 carbon atoms, substituted thioalkyl of about 5 to about 50 carbon atoms, aryl of about 5 to about 50 carbon atoms, aryloxy of about 5 to about 50 carbon atoms, thioaryl of about 5 to about 50 carbon atoms, alkylaryl of about 5 to about 50 carbon atoms, and corresponding substituted moieties thereof; in some embodiments, each R₇ is independently selected from the group consisting alkyl of about 10 to about 50 carbon atoms, substituted alkyl of about 10 to about 50 carbon atoms, alkenyl of about 10 to about 50 carbon atoms, substituted alkenyl of about 10 to about 50 carbon atoms, alkynyl of about 10 to about 50 carbon atoms, substituted alkynyl of about 10 to about 50 carbon atoms, alkoxy of about 10 to about 50 carbon atoms, substituted alkoxy of about 10 to about 50 carbon atoms, alkenoxy of about 10 to about 50 carbon atoms, substituted alkenoxy of about 10 to about 50 carbon atoms, alkynoxy of about 10 to about 50 carbon atoms, substituted alkynoxy of about 10 to about 50 carbon atoms, thioalkyl of about 10 to about 50 carbon atoms, substituted thioalkyl of about 10 to about 50 carbon atoms, aryl of about 10 to about 50 carbon atoms, aryloxy of about 10 to about 50 carbon atoms, thioaryl of about 10 to about 50 carbon atoms, alkylaryl of about 10 to about 50 carbon atoms, and corresponding substituted moieties thereof; in some embodiments, each R₇ is independently selected from the group consisting of alkyl of about 5 to about 40 carbon atoms, substituted alkyl of about 5 to about 40 carbon atoms, alkenyl of about 5 to about 40 carbon atoms, substituted alkenyl of about 5 to about 40 carbon atoms, alkynyl of about 5 to about 40 carbon atoms, substituted alkynyl of about 5 to about 40 carbon atoms, alkoxy of about 5 to about 40 carbon atoms, substituted alkoxy of about 5 to about 40 carbon atoms, alkenoxy of about 5 to about 40 carbon atoms, substituted alkenoxy of about 5 to about 40 carbon atoms, alkynoxy of about 5 to about 40 carbon atoms, substituted alkynoxy of about 5 to about 40 carbon atoms, thioalkyl of about 5 to about 40 carbon atoms, substituted thioalkyl of about 5 to about 40 carbon atoms, aryl of about 5 to about 40 carbon atoms, aryloxy of about 5 to about 40 carbon atoms, thioaryl of about 5 to about 40 carbon atoms, alkylaryl of about 5 to about 40 carbon atoms, and corresponding substituted moieties thereof; in some embodiments, each R₇ is independently selected from the group consisting of alkyl of about 15 to about 50 carbon atoms, substituted alkyl of about 15 to about 50 carbon atoms, alkenyl of about 15 to about 50 carbon atoms, substituted alkenyl of about 15 to about 50 carbon atoms, alkynyl of about 15 to about 50 carbon atoms, substituted alkynyl of about 15 to about 50 carbon atoms, alkoxy of about 15 to about 50 carbon atoms, substituted alkoxy of about 15 to about 50 carbon atoms, alkenoxy of about 15 to about 50 carbon atoms, substituted alkenoxy of about 15 to about 50 carbon atoms, alkynoxy of about 15 to about 50 carbon atoms, substituted alkynoxy of about 15 to about 50 carbon atoms, thioalkyl of about 15 to about 50 carbon atoms, substituted thioalkyl of about 15 to about 50 carbon atoms, aryl of about 15 to about 50 carbon atoms, aryloxy of about 15 to about 50 carbon atoms, thioaryl of about 15 to about 50 carbon atoms, alkylaryl of about 15 to about 50 carbon atoms, and corresponding substituted moieties thereof; in some embodiments, each R₇ is independently selected from the group consisting of alkyl of about 20 to about 50 carbon atoms, substituted alkyl of about 20 to about 50 carbon atoms, alkenyl of about 20 to about 50 carbon atoms, substituted alkenyl of about 20 to about 50 carbon atoms, alkynyl of about 20 to about 50 carbon atoms, substituted alkynyl of about 20 to about 50 carbon atoms, alkoxy of about 20 to about 50 carbon atoms, substituted alkoxy of about 20 to about 50 carbon atoms, alkenoxy of about 20 to about 50 carbon atoms, substituted alkenoxy of about 20 to about 50 carbon atoms, alkynoxy of about 20 to about 50 carbon atoms, substituted alkynoxy of about 20 to about 50 carbon atoms, thioalkyl of about 20 to about 50 carbon atoms, substituted thioalkyl of about 20 to about 50 carbon atoms, aryl of about 20 to about 50 carbon atoms, aryloxy of about 20 to about 50 carbon atoms, thioaryl of about 20 to about 50 carbon atoms, alkylaryl of about 20 to about 50 carbon atoms, and corresponding substituted moieties thereof; in some embodiments, the total number of carbon atoms in R₅, R₆ and R₇ is at least 10, or at least 15, or at least 20, or at least 25, or at least 30, for example.

The polymer is synthesized according to standard polymer chemistry using the appropriate monomeric units identified above. In some embodiments, each block of the functionalized polymer is prepared separately by polymerizing the starting monomeric unit. Then, the blocks are assembled into the block polymer by a “living polymerization method.” In the living polymerization method, the blocks are assembled stepwise. For example, with respect to the polymer embodiment comprising two blocks, the first block is fabricated to have a reactive ending group to which the second block monomer is added to make the two-block polymer. In some embodiments, monomer units, each in a different functionalized form, may be combined in a single polymerization step. As mentioned above, in this latter polymerization approach, the number of monomer units in each block may be controlled by controlling the molar concentration of the monomer units to effectively tune the ability of the polymer for binding to a nanoparticle and the stability and solubility or dispersibility of the polymer and resulting functionalized polymer-nanoparticle composition.

Polymerization techniques include, for example, condensation (step reaction) polymerization, addition (chain reaction) polymerization (anionic, etc.), coordination polymerization, emulsion polymerization, ring opening polymerization, solution polymerization, step-growth polymerization, plasma polymerization, Ziegler process, radical polymerization, atom transfer radical polymerization, reversible addition fragmentation and chain transfer polymerization, and nitroxide mediated polymerization, for example. The conditions for the polymerization such as temperature, reaction medium, pH, duration, and the order of addition of the reagents, for example, are dependent on the type of polymerization employed, the nature of the monomer reagents including any functional group employed, and the nature of any catalyst employed, for example. Such conditions are generally known since the types of polymerization techniques that can be used are known in the art.

In an example, by way of illustration and not limitation, embodiments of functionalized polymer I may be formed from the following monomer block units:

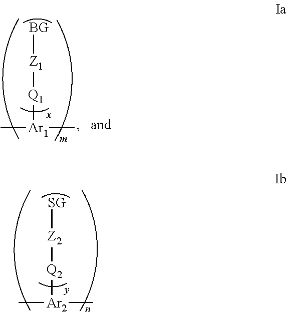

wherein BG, SG, Q₁, Z₁, Q₂, Z₂, m, n, x and y are as defined above.

Monomer block unit Ia may be formed from monomer units of the formulas:

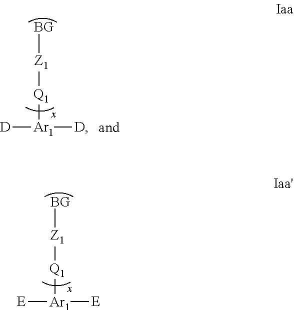

wherein D is a functional group and E is a functional group that is complementary to D and reacts with D to form a covalent bond linking Iaa and Iaa′ in, for example, a metal catalyzed polymerization.

In a similar manner, monomer block unit Ib may be formed from monomer units of the formulas:

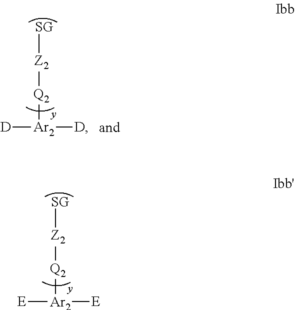

wherein D is a functional group and E is a functional group that is complementary to D and reacts with D to form a covalent bond linking Ibb and Ibb′ in, for example, a metal catalyzed polymerization.

In one approach, linking together Ia and Ib by a direct bond or by a linking group results in the formation of functionalized polymer I. In this approach, Ia and Ib comprise appropriate functionalities for linking as discussed herein.

In another approach, block monomer unit Ia is prepared as discussed above. Then, monomer Ibb and Ibb′ are combined with Ia and polymerization is carried out to form functionalized copolymer I. The polymerization employed may be, for example, a metal-catalyzed polymerization, and the like. The above process may also be carried out by employing block monomer unit Ib and polymerizing Ib with Iaa and Iaa′.

By way of example and not limitation, in some embodiments, D may comprise a halogen group such as, e.g., bromide, chloride or iodide. In some embodiments, D may be a sulfonic acid such as, e.g., a tosylate, or a triflate. By way of example and not limitation, in some embodiments, E may comprise an organometallic functional group, a boronic ester, a silicon reagent, or a Grignard reagent.

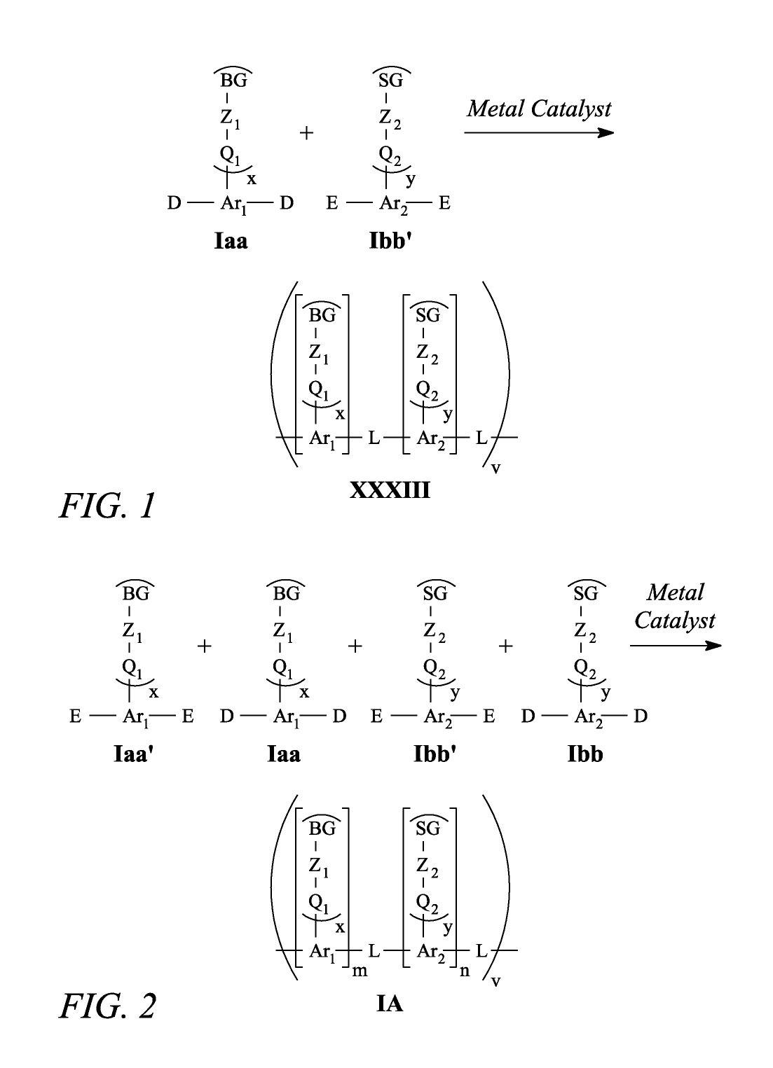

An example of the formation of an embodiment of a polymer in accordance with polymer I from the polymerization of Iaa and Ibb′ is set forth in FIG. 1. In the embodiment, a polymer XXXIII is formed wherein m and n (of polymer I) are both 1. The polymerization is carried out in the presence of a metal catalyst. The nature of the metal catalyst is dependent on the nature of the polymerization, and the nature of D and E, for example. The metal catalyst may be, for example, palladium, platinum, zinc, ruthenium, nickel, copper, cobalt, rhodium, or iridium.

Another example of the formation of an embodiment of a polymer in accordance with polymer I from the polymerization of Iaa, Iaa′, Ibb and Ibb′ is set forth in FIG. 2. In the embodiment shown, polymer IA is formed wherein m and n are both greater than 1. The polymerization is carried out in the presence of a metal catalyst. The nature of the metal catalyst is dependent on the nature of the polymerization, and the nature of D and E, for example. The metal catalyst may be, for example, palladium, platinum, zinc, ruthenium, nickel, copper, cobalt, rhodium, or iridium.

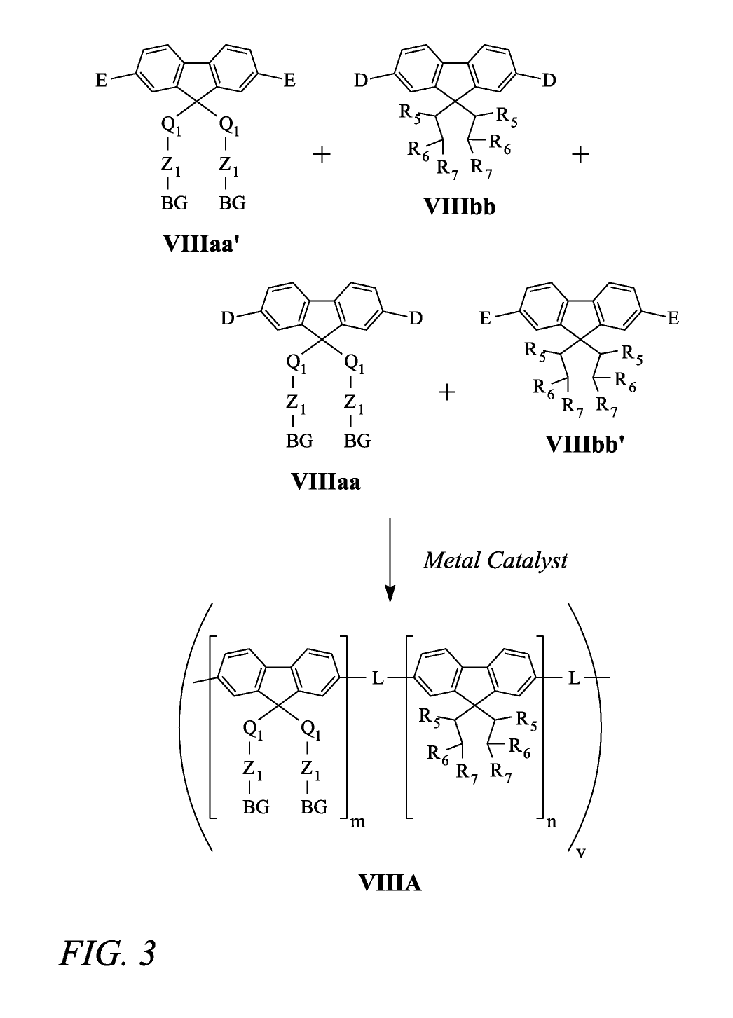

In an example by way of illustration and not limitation, embodiments in accordance with polymer VIIIA may be formed by polymerizing the following monomer units using, for example, a nickel-catalyzed polymerization (see FIG. 3).

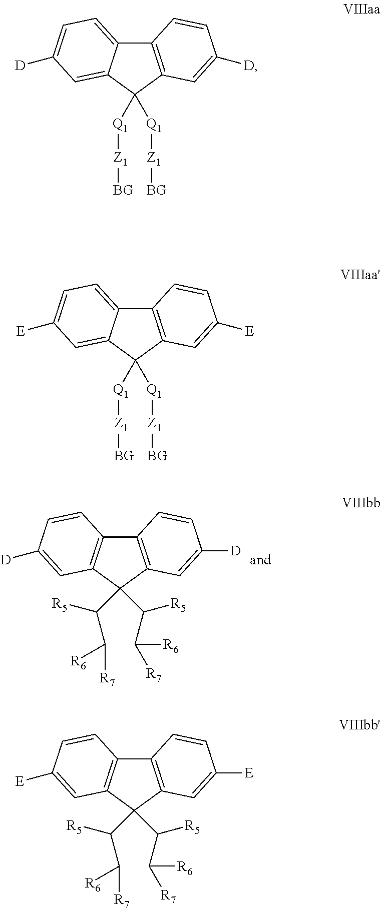

wherein BG, Q₁, Z₁, m, n, R₅, R₆ and R₇ are as defined above, and wherein D is a functional group and E is a functional group that is complementary to D and reacts with D to form a covalent bond.

In an example by way of illustration and not limitation, embodiments in accordance with polymer VIII may be formed by polymerizing the following block units using, for example, a metal-catalyzed polymerization.

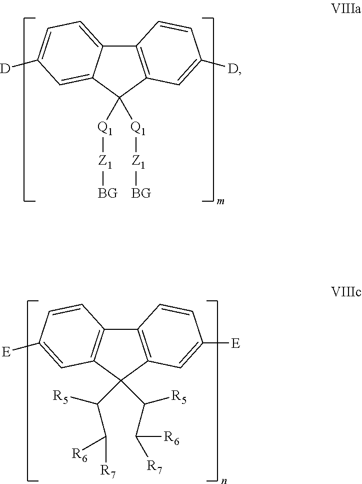

wherein BG, Q₁, Z₁, m, n, R₅, R₆ and R₇ are as defined above, and
wherein D is a functional group and E is a functional group that is complementary to D and reacts with D to form a covalent bond.

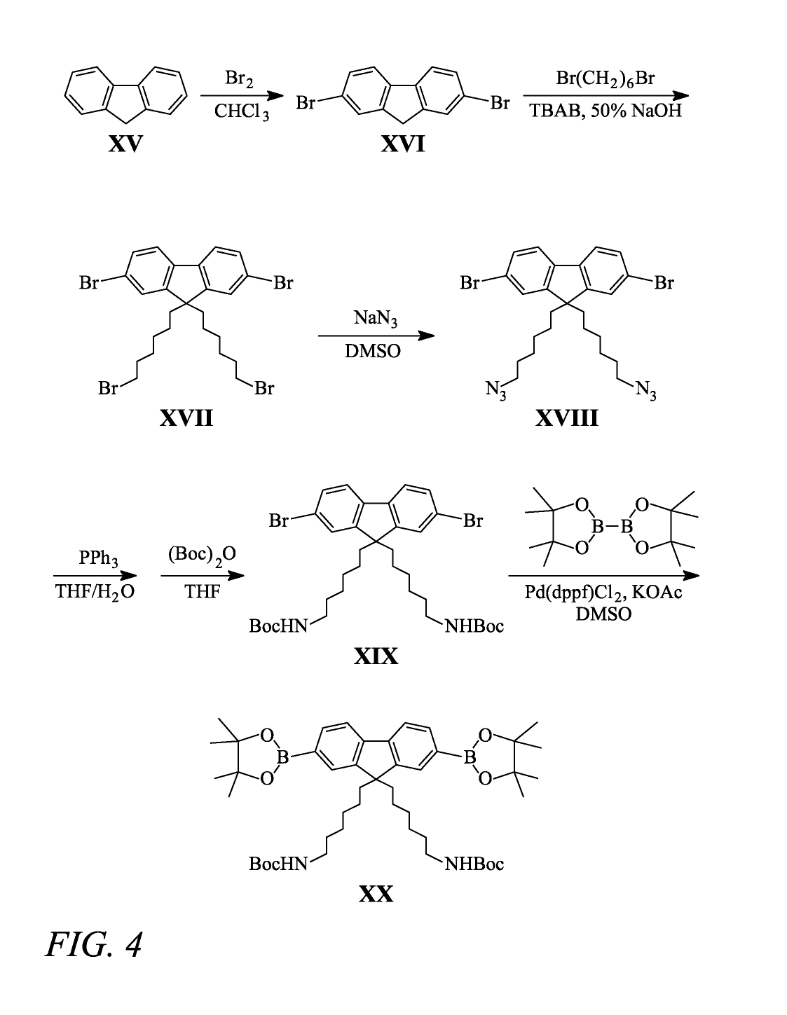

Another example, by way of illustration and not limitation, of a synthesis of functionalized polymers in accordance with the present embodiments is set forth in FIGS. 4-6. Referring to FIG. 4, fluorene XV may be brominated to give XVI by reaction with liquid bromine in a suitable organic solvent such as, e.g., chloroform, methylene chloride, and dimethylformamide (DMF). The reaction may be carried out at a temperature of about 0° C. to about 20° C. for a period of about 1 to about 30 hours. Excess bromine may be removed by treatment with a base such as, e.g., NaOH, KOH, Na₂SO₃ and NaHSO₃.

XVI may be reacted to give XVII by reaction with 1,6-dibromohexane in the presence of tetrabutylammonium bromide (TBAB) in aqueous (40-60%) alkaline hydroxide such as, e.g., NaOH and KOH. The reaction may be carried out at a temperature of about 10° C. to about 100° C. under an inert gas such as, e.g., nitrogen, and argon for a period of about 1 to about 30 hours.

Conversion of XVII to azide XVIII may be carried out by treating XVII with sodium azide in a suitable solvent such as, e.g., dimethysulfoxide (DMSO), acetone and DMF. The reaction may be carried out at a temperature of about 10° C. to about 100° C. for a period of about 1 to about 30 hours.

XVIII may be treated to form protected amine XIX by reaction with triphenyl-phosphine (PPh₃) in an aqueous organic solvent such as, e.g., aqueous ether, such as tetrahydrofuran (THF) for example. The reaction may be carried out at a temperature of about 10° C. to about 60° C. for a period of about 1 to about 30 hours. Next, a product XIX with a protected amine group is formed by treatment of XIX with a protecting agent, for example, di-t-butyl carbonate (Boc-anhydride) (Boc₂O) in an organic solvent such as, e.g., an ether, such as THF, and methylene chloride. The reaction may be carried out at a temperature of about 10° C. to about 60° C. for a period of about 1 to about 10 hours. Other protecting agents may be employed such as, e.g., acetic anhydride, and acetyl chloride.

Borate ester XX may be obtained from XIX by treatment of XIX with a suitable borane ester such as, e.g., bis(pinacolato)diborane, in the presence of a catalyst such as, e.g., a palladium catalyst, e.g., bis(ethylenediamine)palladium(II) chloride (Pd(dppf)Cl₂, and tris(dibenzylideneacetone)dipalladium (Pd₂(dba)₃) in a suitable solvent such as, e.g., DMSO, DMF, and 1,4-dioxane in the presence of a suitable base such as, e.g., potassium acetate (KOAc) and sodium acetate. The reaction may be carried out at a temperature of about 20° C. to about 100° C. for a period of about 1 to about 20 hours.

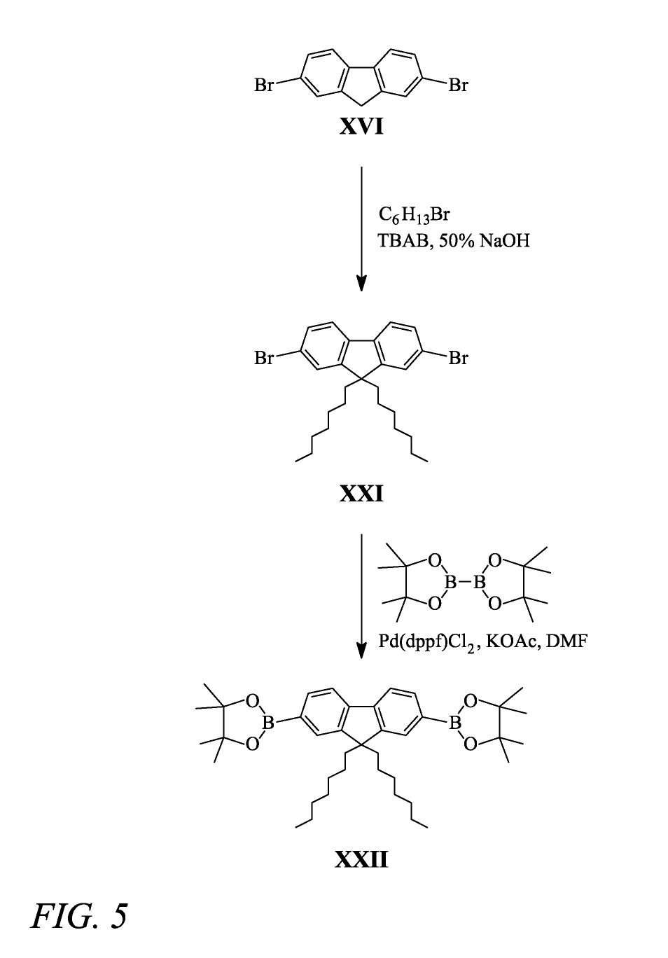

Referring to FIG. 5, brominated fluorine XVI may be reacted to give XXI by reaction with 1-bromohexane in the presence of tetrabutylammonium bromide (TBAB) in aqueous (40-60%) alkaline hydroxide such as, e.g., NaOH and KOH. The reaction may be carried out at a temperature of about 0° C. to about 100° C. under an inert gas for a period of about 1 to about 30 hours.

Borate ester XXII may be obtained from XXI by treatment of XXI with a suitable borane ester such as, e.g., bis(pinacolato)diborane, in the presence of a catalyst such as, e.g., a palladium catalyst, e.g., Pd(dppf)Cl₂, Pd₂(dba)₃ in a suitable organic solvent such as, e.g., DMSO, and DMF in the presence of a suitable base such as, e.g., potassium acetate (KOAc) and sodium acetate. The reaction may be carried out at a temperature of about 20° C. to about 100° C. for a period of about 1 to about 20 hours.

By way of illustration and not limitation, other specific embodiments of functionalized polymers in accordance with the present embodiments have the following formulas, wherein the block units may be connected by a bond or a chemical moiety:

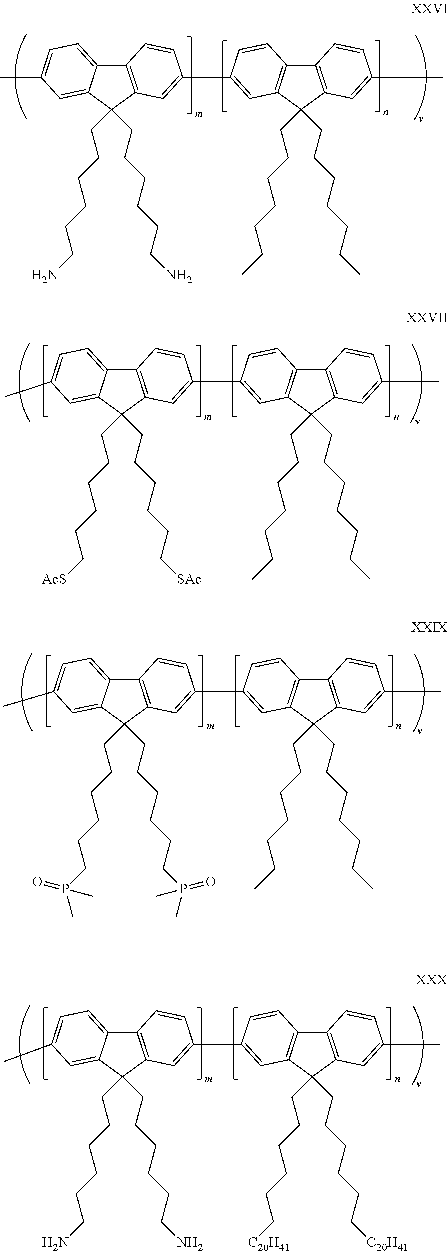

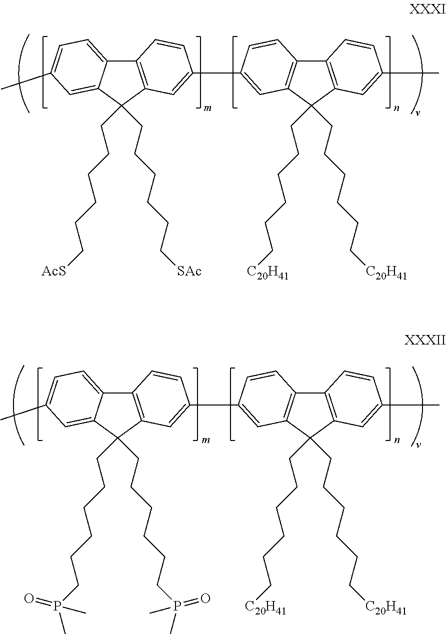

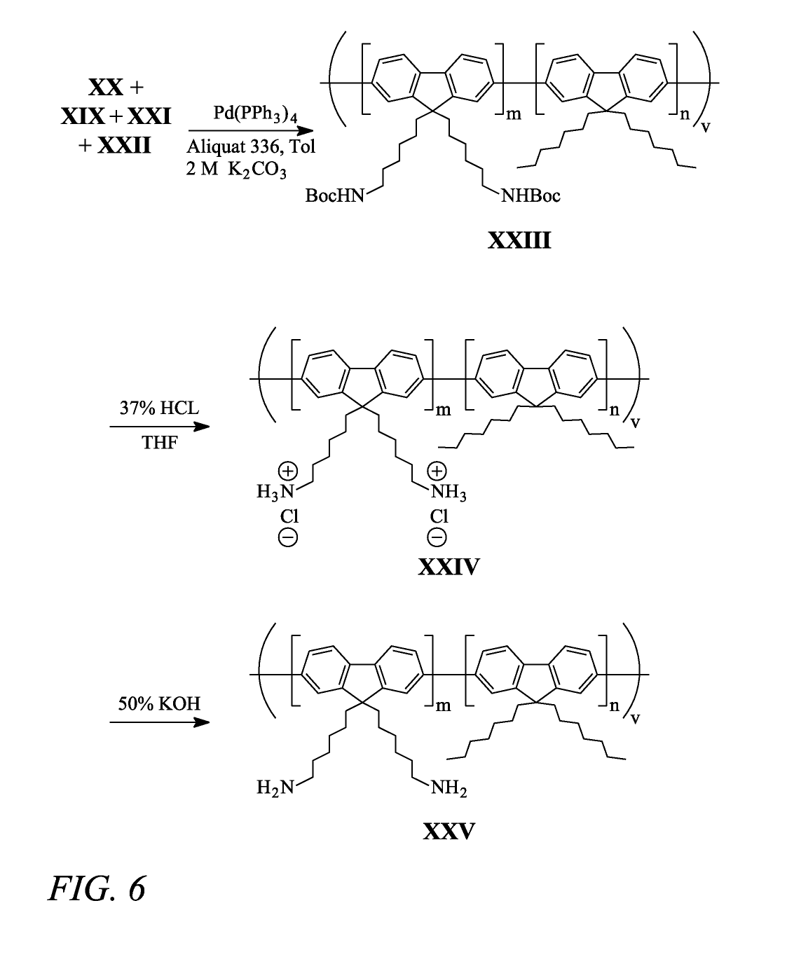

An example, by way of illustration and not limitation, of the formation of a specific embodiment (XXV wherein m and n are at least 2) of a functionalized polymer in accordance with the present embodiments is set forth in FIG. 6. XXV is formed from monomer units XIX, XX, XXI and XXII, which are combined in the presence of a metal catalyst such as, e.g., a palladium catalyst (tetra-triphenylphosphine) palladium, palladium, platinum, zinc, ruthenium, nickel, copper, cobalt, rhodium, and iridium to yield Boc protected amine polymer XXIII wherein m and n are at least 2. The reaction is carried out in a suitable aqueous organic solvent such as, e.g., a combination of water and toluene, water and an ether, e.g., THF. The reaction mixture may also comprise a base such as, e.g., sodium carbonate, and potassium carbonate. The reaction mixture may also comprise a phase transfer catalyst such as, e.g., ALIQUAT 336®, tetrabutylammonium bromide (TBAB), and tetrabutylammonium iodide (TBAI). ALIQUAT 336® is a trademark of Cognis Corp. with an IUPAC name of N-Methyl-N,N-dioctyloctan-1-aminium chloride. The reaction may be carried out at a temperature of about 80° to about 120° C. for a period of about 10 to about 60 hours. The molar concentration of XIX, XX, XXI and XXII may be adjusted to adjust the value of m and n in the resulting polymer.

XXIII may be converted to functionalized polymer XXIV (wherein m and n are at least 2) having ammonium chloride groups by treatment with hydrochloric acid in an organic solvent such as, an ether, e.g., THF, methylene chloride and chloroform. The reaction may be carried out at a temperature of about 0° C. to about 60° C. for a period of about 10 to about 80 hours. Hydrolysis of the ammonium chloride groups of XXIV may be achieved by, for example, treatment of XXIV with an aqueous (about 40 to about 60%) base such as, e.g., KOH, NaOH, K₂CO₃ and triethylamine (TEA) in a suitable organic solvent such as, e.g., chloroform, methylene chloride, and an ether, e.g., THF. The reaction may be carried out at a temperature of about 0° C. to about 60° C. for a period of about 0.5 to about 10 hours. The resulting product is functionalized polymer XXV wherein m and n are at least 2.

### Specific Embodiments of Polymer-Nanoparticle Compositions

The functionalized polymers in accordance with the present embodiments are employed to prepare polymer-nanoparticle compositions that comprise nanoparticles and a functionalized polymer. In various embodiments, the nanoparticles are particles that may be of the same type or composition, or of two or more different types or compositions, and that have cross-sectional dimensions in a range from about 1 nanometer (nm) to about 500 nm, or from about 1 nm to about 400 nm, or from about 1 nm to about 300 nm, or from about 1 nm to about 200 nm, or from about 1 nm to about 100 nm, or from about 1 nm to about 50 nm, or from about 5 nanometer (nm) to about 500 nm, or from about 5 nm to about 400 nm, or from about 5 nm to about 300 nm, or from about 5 nm to about 200 nm, or from about 5 nm to about 100 nm, or from about 5 nm to about 50 nm, or from about 10 nanometer (nm) to about 500 nm, or from about 10 nm to about 400 nm, or from about 10 nm to about 300 nm, or from about 10 nm to about 200 nm, or from about 10 nm to about 100 nm, or from about 10 nm to about 50 nm.

In some embodiments, each nanoparticle comprises a substantially pure element. In some embodiments, each nanoparticle comprises a binary, tertiary or quaternary compound. In some embodiments, the nanoparticle comprises an element selected from the group of elements (based on the periodic table of the elements) consisting of Group 2 (IIA) elements, Group 12 (IIB) elements, Group 13 (IIIA) elements, Group 3 (IIIB) elements, Group 14 (IVA) elements, Group 4 (IVB) elements, Group 15 (VA) elements, Group 5 (VB) elements, Group 16 (VIA) elements and Group 6 (VIB) elements and combinations of elements from one or more of the aforementioned groups.

In some embodiments, each nanoparticle may comprise a substantially pure element. In additional embodiments, each nanoparticle may include a binary, tertiary, or quaternary compound. Each nanoparticle may comprise one or more elements selected from Groups 2 (IIA), 12 (IIB), 3 (IIIB), 4 (IVB), 5 (VB) and 6 (VIB) of the periodic table.

In some embodiments, the nanoparticle comprises a metallic material such as, for example, gold, silver, platinum, copper, iridium, palladium, iron, nickel, cobalt, titanium, hafnium, zirconium, and zinc and alloys thereof, and oxides or sulfides thereof. Some oxides of a metallic material include, but are not limited to, Group 4 (IVB) oxides, such as TiO₂, ZrO₂, and HfO₂; and Groups 8-10 (VIII) oxides, such as Fe₂O₃, CoO, and NiO, for example.

In some embodiments, each nanoparticle comprises a semiconductive material. By way of example and not limitation, each nanoparticle may comprise a III-V type compound semiconductor material (including, but not limited to, InP, InAs, GaAs, GaN, GaP, Ga₂S₃, In₂S₃, In₂Se₃, In₂Te₃, InGaP, and InGaAs), or a II-VI type compound semiconductor material (including, but not limited to, ZnO, CdSe, CdS, CdTe, ZnS, ZnSe, ZnTe, HgS, HgSe, and HgTe).

In some embodiments, each nanoparticle has a core-shell structure. For example, each nanoparticle may have an inner core region comprising a semiconductive material and an outer shell region comprising a passive inorganic material.

In some embodiments, each nanoparticle has an inner core region comprising: (a) a first element selected from Groups 2 (IIA), 12 (IIB), 13 (IIIA) 14 (IVA) and a second element selected from Group 16 (VIA); (b) a first element selected from Group 13 (IIIA) and a second element selected from Groups 15 (VA); or (c) an element selected from Group 14 (IVA). Examples of materials suitable for use in the semiconductive core include, but are not limited to, CdSe, CdTe, CdS, ZnSe, InP, InAs, or PbSe. Additional examples include MgS, MgSe, MgTe, CaS, CaSe, CaTe, SrS, SrSe, SrTe, BaS, BaSe, BaTe, ZnS, ZnTe, HgS, HgSe, HgTe, Al₂S₃, Al₂Se₃, Al₂Te₃, Ga₂S₃, Ga₂Se₃, GaTe, In₂S₃, In₂Se₃, InTe, SnS, SnSe, SnTe, PbS, PbSe, PbTe, AlP, AlAs, AlSb, GaN, GaP, GaAs, GaSb, InN, InSb, BP, Si, and Ge. Furthermore, the inner core region of each nanocrystal may comprise a binary, ternary or quaternary mixture, compound, or solid solution of any such elements or materials.

In some embodiments, each nanoparticle has an outer shell region comprising any of the materials previously described as being suitable for the inner core region of the nanoparticle. The outer shell region, however, may include a material that differs from the material of the inner core region. By way of example and not limitation, the outer shell region of each nanoparticle may include CdSe, CdS, ZnSe, ZnS, CdO, ZnO, SiO₂, Al₂O₃, or ZnTe. Additional examples include MgO, MgS, MgSe, MgTe, CaO, CaS, CaSe, CaTe, SrO, SrS, SrSe, SrTe, BaO, BaS, BaSe, BaTe, CdTe, HgO, HgS, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, GeO₂, SnO, SnO₂, SnS, SnSe, SnTe, PbO, PbO₂, PbS, PbSe, PbTe, MN, AlP, AlAs, AlSb, GaN, GaP, GaAs, GaSb, InN, and BP. Furthermore, the outer shell region of each nanoparticle may include a semiconductive material or an electrically insulating (i.e., non-conductive) material.

In some embodiments, a polymer-nanoparticle composition has the formula:

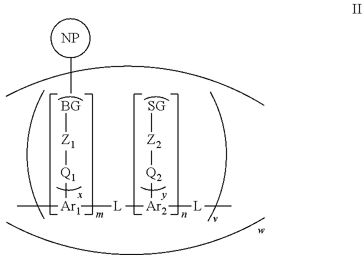

wherein:

BG is a binding group that is bound to a nanoparticle,

Z₁ is independently a covalent bond or a chemical moiety providing a covalent bond between BG and Q₁,

Z₂ is independently a covalent bond or a chemical moiety providing a covalent bond between SG and Q₂,

Q₁ is a carbon atom or a heteroatom,

Q₂ is a carbon atom or a heteroatom,

Ar₁ is an aromatic ring moiety,

Ar₂ is an aromatic ring moiety,

L is independently a covalent bond directly linking Ar₁ and Ar₂ or a chemical moiety linking Ar₁ and Ar₂,

w is an integer between about 2 and about 100,

m and n are integers independently between 1 and about 5,000,

v is an integer greater than about 10,

x and y are integers independently between 1 and about 5,

SG is a hydrophobic moiety that provides for steric stabilization and homogeneity of mixtures of the nanoparticle in a non-polar medium with the proviso that, if m is 1, SG comprises at least 25 carbon atoms, and

NP is a nanoparticle.

The number of polymer units bound to the nanoparticle by means of BG depends on the nature of the nanoparticle, the size of the nanoparticle, and the nature of BG, for example. In some embodiments, the number of polymer units (w) bound to the nanoparticle is about 2 to about 100, or about 2 to about 75, or about 2 to about 50, or about 2 to about 40, or about 2 to about 30, or about 2 to about 20, or about 2 to about 10, or about 2 to about 5, or about 2 to about 4, or about 2 to about 3, or about 3 to about 100, or about 3 to about 75, or about 3 to about 50, or about 3 to about 40, or about 3 to about 30, or about 3 to about 20, or about 3 to about 10, or about 3 to about 5, or about 3 to about 4, or about 4 to about 100, or about 4 to about 75, or about 4 to about 50, or about 4 to about 40, or about 4 to about 30, or about 4 to about 20, or about 4 to about 10, or about 4 to about 5, or about 5 to about 100, or about 5 to about 75, or about 5 to about 50, or about 5 to about 40, or about 5 to about 30, or about 5 to about 20, or about 5 to about 10, or about 5 to about 9, or about 5 to about 8, or about 5 to about 7, for example.

In the above embodiment, wherein w is 4, the polymer-nanoparticle composition has the formula XXXV:

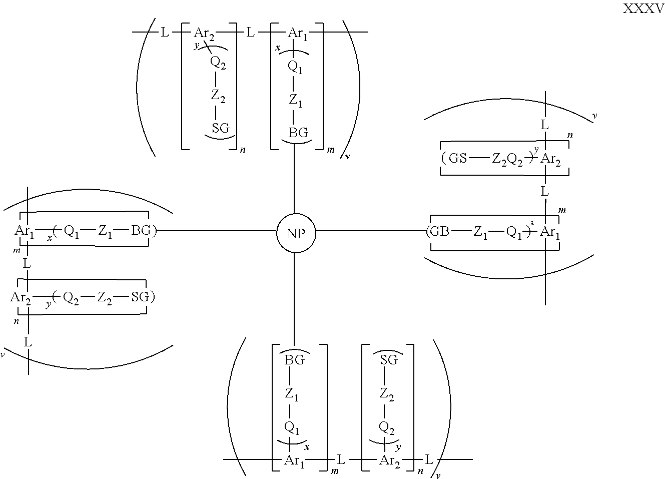

wherein:

BG is a binding group that is bound to the nanoparticle,

Z₁ is independently a covalent bond or a chemical moiety providing a covalent bond between BG and Q₁,

Z₂ is independently a covalent bond or a chemical moiety providing a covalent bond between SG and Q₂,

Q₁ is a carbon atom or a heteroatom,

Q₂ is a carbon atom or a heteroatom,

Ar₁ is an aromatic ring moiety,

Ar₂ is an aromatic ring moiety,

L is independently a covalent bond directly linking Ar₁ and Ar₂ or a chemical moiety linking Ar₁ and Ar₂,

w is 4,

m and n are integers independently between 1 and about 5,000,

v is an integer greater than about 10,

x and y are integers independently between 1 and about 5,

SG is a hydrophobic moiety that provides for steric stabilization and homogeneity of mixtures of the nanoparticle in a non-polar medium with the proviso that, if m is 1, SG comprises at least 25 carbon atoms, and

NP is a nanoparticle.

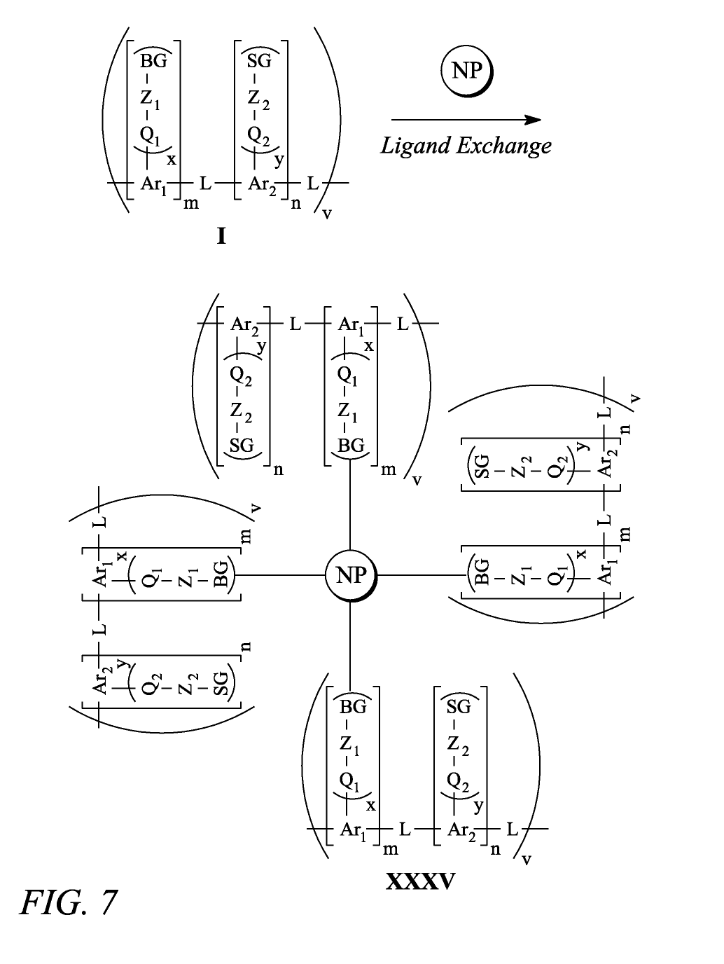

The formation of functionalized polymer-nanoparticle composition XXXV is shown in FIG. 7 by way of illustration and not limitation. Functionalized polymer I may be reacted with a nanoparticle NP so that BG binds to the nanoparticle. Various functionalities are set forth above for BG and the nanoparticle. In some embodiments, the reaction of the polymer with the nanoparticle involves ligand exchange. In the example shown in FIG. 7, functionalized polymer I is mixed with nanoparticles in a non-polar solvent. A ligand exchange reaction takes place to achieve a functionalized polymer-nanoparticle composition XXXV that is stable and highly dispersible in the non-polar medium.

In some embodiments, a functionalized polymer-nanoparticle composition has the formula XXXVI:

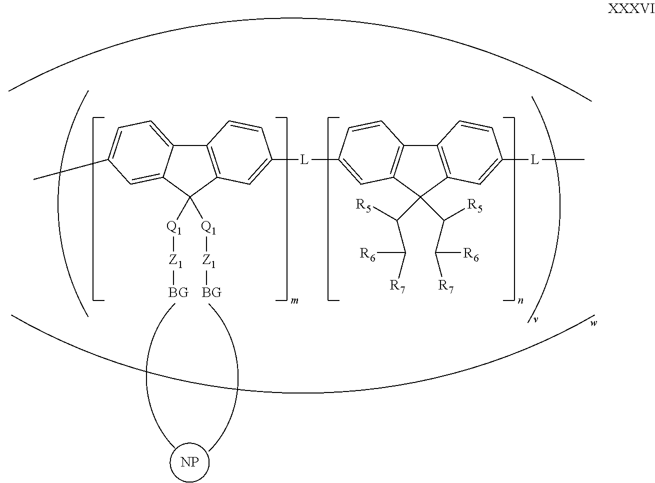

BG is independently selected from the group consisting of primary amines, secondary amines, tertiary amines, amides, nitriles, isonitriles, cyanates, isocyanates, thiocyanates, isothiocyanates, azides, thiols, thiolates, sulfides, sulfinates, sulfonates, phosphates, hydroxyls, alcoholates, phenolates, carbonyls, carboxylates, phosphines, phosphine oxides, phosphonic acids, phosphoramides and phosphates,

Z₁ is independently selected from the group consisting of a covalent bond and a chemical moiety selected from the group consisting of alkylene of 1 to about 30 carbon atoms, substituted alkylene of 1 to about 30 carbon atoms, alkylenoxy of 1 to about 30 carbon atoms, substituted alkylenoxy of 1 to about 30 carbon atoms, thioalkylene of 1 to about 30 carbon atoms, substituted thioalkylene of 1 to about 30 carbon atoms, alkenylene of 1 to about 30 carbon atoms, substituted alkenylene of 1 to about 30 carbon atoms, alkenylenoxy of 1 to about 30 carbon atoms, substituted alkenylenoxy of 1 to about 30 carbon atoms, thioalkenylene of 1 to about 30 carbon atoms, substituted thioalkenylene of 1 to about 30 carbon atoms, alkynylene of 1 to about 30 carbon atoms, substituted alkynylene of 1 to about 30 carbon atoms, alkynylenoxy of 1 to about 30 carbon atoms, substituted alkynylenoxy of 1 to about 30 carbon atoms, thioalkynylene of 1 to about 30 carbon atoms, substituted thioalkynylene of 1 to about 30 carbon atoms, arylene of 1 to about 30 carbon atoms, substituted arylene of 1 to about 30 carbon atoms, arylenoxy of 1 to about 30 carbon atoms, thioarylene of 1 to about 30 carbon atoms, and counterparts of the above comprising one or more heteroatoms; or in some embodiments, the chemical moiety is selected from the group consisting of alkylene of 1 to 30 carbon atoms, arylene of 1 to 30 carbon atoms, substituted alkylene of 1 to 30 carbon atoms, substituted arylene of 1 to 30 carbon atoms, arylenoxy of 1 to about 30 carbon atoms, thioarylene of about 1 to about 30 carbon atoms, substituted arylenoxy of 1 to about 30 carbon atoms, substituted thioarylene of about 1 to about 30 carbon atoms, and counterparts of the above comprising one or more heteroatoms, providing a covalent bond between BG and Q₁,

Q₁ is a carbon atom or a heteroatom,

L is independently a covalent bond or a linking group selected from the group consisting of:

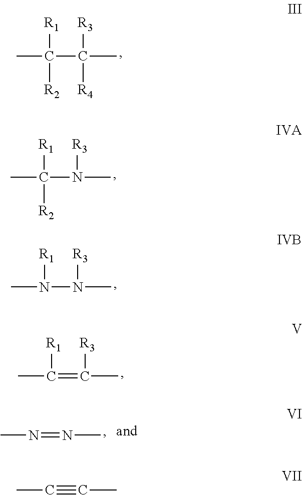

wherein R₁, R₂, R₃, R₄ are each independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl),

m and n are integers independently between 1 and about 5,000,

v is an integer greater than about 10,

w is an integer between about 2 and about 100,

each R₅ is independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl),

each R₆ is independently selected from the group consisting of hydrogen, alkyl, substituted alkyl, heteroalkyl (e.g., alkoxy, substituted alkoxy, thioalkyl, substituted thioalkyl), alkyl, substituted alkenyl, heteroalkenyl (e.g., alkenoxy, substituted alkenoxy, thioalkenyl, substituted thioalkenyl), alkynyl, substituted alkynyl, heteroalkynyl (e.g., alkynoxy, substituted alkynoxy, thioalkynyl, substituted thioalkynyl), aryl, substituted aryl, heteroaryl (e.g., aryloxy, substituted aryloxy, thioaryl, substituted thioaryl), and

each R₇ is independently selected from the group consisting of alkyl of about 5 to about 50 carbon atoms, substituted alkyl of about 5 to about 50 carbon atoms, alkenyl of about 5 to about 50 carbon atoms, substituted alkenyl of about 5 to about 50 carbon atoms, alkynyl of about 5 to about 50 carbon atoms, substituted alkynyl of about 5 to about 50 carbon atoms, alkoxy of about 5 to about 50 carbon atoms, substituted alkoxy of about 5 to about 50 carbon atoms, alkenoxy of about 5 to about 50 carbon atoms, substituted alkenoxy of about 5 to about 50 carbon atoms, alkynoxy of about 5 to about 50 carbon atoms, substituted alkynoxy of about 5 to about 50 carbon atoms, thioalkyl of about 5 to about 50 carbon atoms, substituted thioalkyl of about 5 to about 50 carbon atoms, aryl of about 5 to about 50 carbon atoms, aryloxy of about 5 to about 50 carbon atoms, thioaryl of about 5 to about 50 carbon atoms, alkylaryl of about 5 to about 50 carbon atoms, and corresponding substituted moieties thereof; in some embodiments, each R₇ is independently selected from the group consisting alkyl of about 10 to about 50 carbon atoms, substituted alkyl of about 10 to about 50 carbon atoms, alkenyl of about 10 to about 50 carbon atoms, substituted alkenyl of about 10 to about 50 carbon atoms, alkynyl of about 10 to about 50 carbon atoms, substituted alkynyl of about 10 to about 50 carbon atoms, alkoxy of about 10 to about 50 carbon atoms, substituted alkoxy of about 10 to about 50 carbon atoms, alkenoxy of about 10 to about 50 carbon atoms, substituted alkenoxy of about 10 to about 50 carbon atoms, alkynoxy of about 10 to about 50 carbon atoms, substituted alkynoxy of about 10 to about 50 carbon atoms, thioalkyl of about 10 to about 50 carbon atoms, substituted thioalkyl of about 10 to about 50 carbon atoms, aryl of about 10 to about 50 carbon atoms, aryloxy of about 10 to about 50 carbon atoms, thioaryl of about 10 to about 50 carbon atoms, alkylaryl of about 10 to about 50 carbon atoms, and corresponding substituted moieties thereof; in some embodiments, each R₇ is independently selected from the group consisting of alkyl of about 5 to about 40 carbon atoms, substituted alkyl of about 5 to about 40 carbon atoms, alkenyl of about 5 to about 40 carbon atoms, substituted alkenyl of about 5 to about 40 carbon atoms, alkynyl of about 5 to about 40 carbon atoms, substituted alkynyl of about 5 to about 40 carbon atoms, alkoxy of about 5 to about 40 carbon atoms, substituted alkoxy of about 5 to about 40 carbon atoms, alkenoxy of about 5 to about 40 carbon atoms, substituted alkenoxy of about 5 to about 40 carbon atoms, alkynoxy of about 5 to about 40 carbon atoms, substituted alkynoxy of about 5 to about 40 carbon atoms, thioalkyl of about 5 to about 40 carbon atoms, substituted thioalkyl of about 5 to about 40 carbon atoms, aryl of about 5 to about 40 carbon atoms, aryloxy of about 5 to about 40 carbon atoms, thioaryl of about 5 to about 40 carbon atoms, alkylaryl of about 5 to about 40 carbon atoms, and corresponding substituted moieties thereof; in some embodiments, each R₇ is independently selected from the group consisting of alkyl of about 15 to about 50 carbon atoms, substituted alkyl of about 15 to about 50 carbon atoms, alkenyl of about 15 to about 50 carbon atoms, substituted alkenyl of about 15 to about 50 carbon atoms, alkynyl of about 15 to about 50 carbon atoms, substituted alkynyl of about 15 to about 50 carbon atoms, alkoxy of about 15 to about 50 carbon atoms, substituted alkoxy of about 15 to about 50 carbon atoms, alkenoxy of about 15 to about 50 carbon atoms, substituted alkenoxy of about 15 to about 50 carbon atoms, alkynoxy of about 15 to about 50 carbon atoms, substituted alkynoxy of about 15 to about 50 carbon atoms, thioalkyl of about 15 to about 50 carbon atoms, substituted thioalkyl of about 15 to about 50 carbon atoms, aryl of about 15 to about 50 carbon atoms, aryloxy of about 15 to about 50 carbon atoms, thioaryl of about 15 to about 50 carbon atoms, alkylaryl of about 15 to about 50 carbon atoms, and corresponding substituted moieties thereof; in some embodiments, each R₇ is independently selected from the group consisting of alkyl of about 20 to about 50 carbon atoms, substituted alkyl of about 20 to about 50 carbon atoms, alkenyl of about 20 to about 50 carbon atoms, substituted alkenyl of about 20 to about 50 carbon atoms, alkynyl of about 20 to about 50 carbon atoms, substituted alkynyl of about 20 to about 50 carbon atoms, alkoxy of about 20 to about 50 carbon atoms, substituted alkoxy of about 20 to about 50 carbon atoms, alkenoxy of about 20 to about 50 carbon atoms, substituted alkenoxy of about 20 to about 50 carbon atoms, alkynoxy of about 20 to about 50 carbon atoms, substituted alkynoxy of about 20 to about 50 carbon atoms, thioalkyl of about 20 to about 50 carbon atoms, substituted thioalkyl of about 20 to about 50 carbon atoms, aryl of about 20 to about 50 carbon atoms, aryloxy of about 20 to about 50 carbon atoms, thioaryl of about 20 to about 50 carbon atoms, alkylaryl of about 20 to about 50 carbon atoms, and corresponding substituted moieties thereof; in some embodiments, the total number of carbon atoms in R₅, R₆ and R₇ is at least 10, or at least 15, or at least 20, or at least 25, or at least 30 for example, with the proviso that, if m is 1, at least one of R₇ comprises at least 25 carbon atoms, and

NP is a nanoparticle.

In some embodiments of XXXVI, where w is 2, a functionalized polymer-nanoparticle composition has the formula XXXVII:

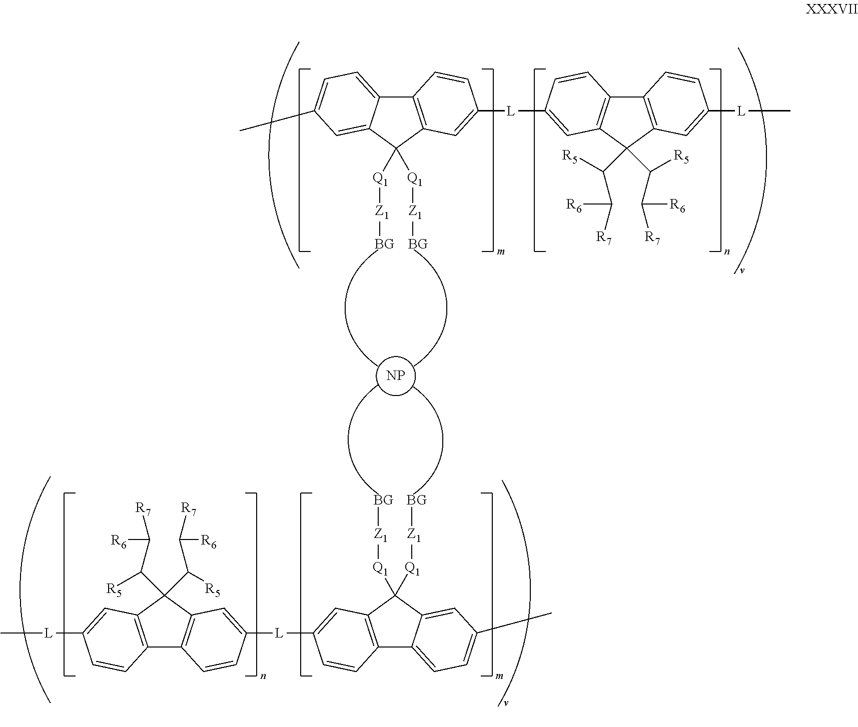

wherein BG, Q₁, Z₁, m, n, v, R₅, R₆ and R₇ are as defined above.

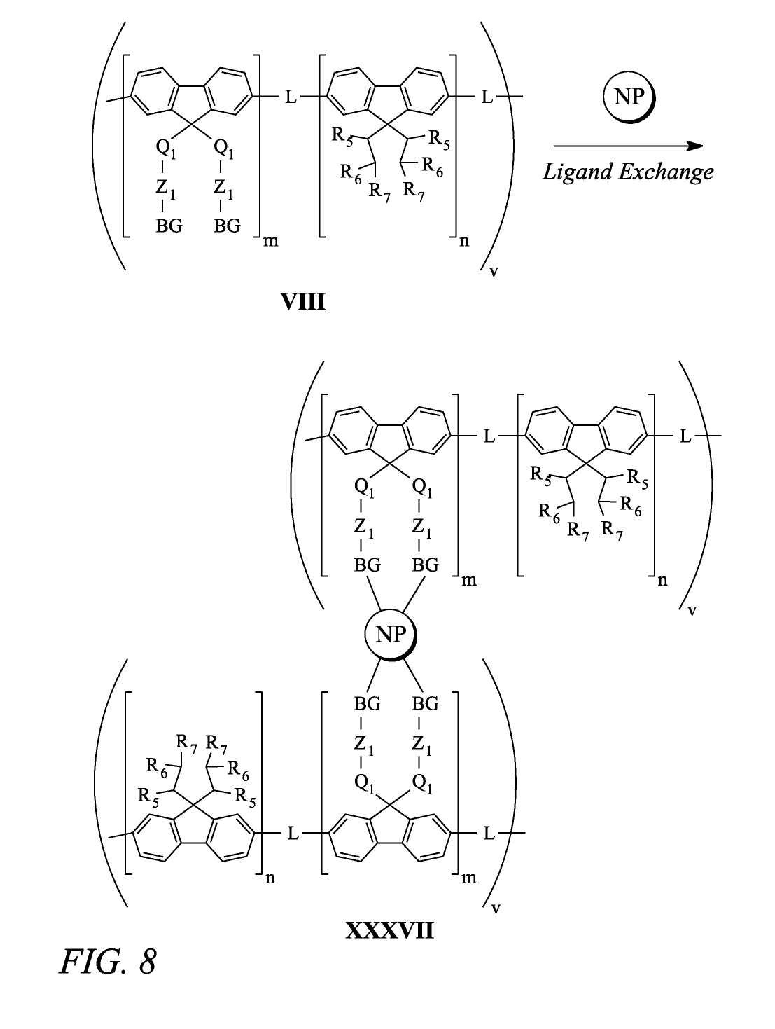

The formation of functionalized polymer-nanoparticle composition XXXVII is shown in FIG. 8 by way of illustration and not limitation. Functionalized polymer VIII may be reacted with a nanoparticle NP so that BG binds to the nanoparticle. In the example shown in FIG. 8, functionalized polymer VIII is mixed with nanoparticles in a non-polar solvent. A ligand exchange reaction takes place to achieve a functionalized polymer-nanoparticle composition XXXVII that is stable and highly dispersible in the non-polar medium.

As discussed above, in some embodiments in the preparation of the polymer-nanoparticle compositions, a ligand exchange reaction is employed. The reaction is usually carried out in a non-polar medium, which may be the same medium as that employed for using the polymer-nanoparticle compositions in various devices as discussed more fully below. The reaction is conducted by mixing the polymer and nanoparticles in the non-polar medium. Generally, the temperature employed during the procedure will be chosen to maximize the binding of the polymer to the nanoparticle, for example. The temperature employed depends on the nature of the BG group on the polymer, the nature of the polymer, the nature of the nanoparticle, the nature of the ligand associated with the particle, and the nature of the non-polar medium, for example. The temperatures for the procedure are generally in a range of from about 0° C. to about 100° C., or from about 10° C. to about 100° C., or from about 20° C. to about 100° C., or from about 25° C. to about 100° C., or from about 20° C. to about 90° C., or from about 20° C. to about 80° C., or from about 20° C. to about 70° C., or from about 20° C. to about 60° C., or from about 20° C. to about 50° C., or from about 20° C. to about 40° C., or from about 20° C. to about 30° C., for example. In some embodiments, the reaction is carried out at ambient temperature. The pH for the medium will usually be in the range of about 3 to about 11, or in the range of about 5 to about 9, or in the range of about 6 to about 8, for example.

### Specific Embodiments of the Use of Polymer-Nanoparticle Compositions

The polymer-nanoparticle compositions may be employed in a variety of applications that involve charged particles and in some embodiments, also involve an applied electric field. Such applications include, for example, light emitting diodes (LED's) for information display applications, electromagnetic radiation sensors, lasers, photovoltaic cells, photo-transistors, modulators, phosphors, photoconductive sensors, and the like. The devices of the aforementioned applications typically comprise a first electrode and a second electrode and have disposed between the first electrode and the second electrode a polymer-nanoparticle composition as described above. Furthermore, because of the enhanced ability of the functionalized polymer-nanoparticle compositions to form homogeneous mixtures, such mixtures can be readily processed in solution-based techniques including, for example, coating methods (for example, spin coating, dip coating, spray coating, and gravure coating), printing methods (for example, screen printing, and inkjet printing). In addition, the functionalized polymers may be designed so that the energy level of the functionalized polymers matches that of electrodes so that the polymer act as a bridge between electrodes and nanoparticles in the functionalized polymer-nanoparticle compositions to facilitate efficient energy transfer from electrodes to nanoparticles.

In some embodiments the functionalized polymer-nanoparticle composition includes nanoparticles chemically attached to molecules of a functionalized polymer as previously described herein and configured to emit electromagnetic radiation having one or more wavelengths within the visible region of the electromagnetic spectrum (e.g., between about 400 nanometers and about 750 nanometers) upon stimulation.

The aforementioned functionalized polymer-luminescent nanoparticle composition may be stimulated by applying a voltage between the anode and the cathode to generate an electric field that extends across the luminescent nanoparticle-polymer composite material. The electrical field between the anode and the cathode generates excitons (e.g., electron-hole pairs) in the luminescent nanoparticle-polymer composite material. The functionalized polymer-luminescent nanoparticle composition may be selectively configured such that the allowed electron-hole energy states of the functionalized polymer and the nanoparticles facilitate transfer of excitons in the functionalized polymer to the nanoparticles. As the excitons in the nanoparticles collapse, a photon of electromagnetic radiation having energy (i.e., a wavelength or frequency) corresponding to the energy of the exciton is emitted.

A particular embodiment of an application of such functionalized polymer-nanoparticle compositions is a light-emitting diode (LED) for information display. The structure of a basic organic light emitting diode comprises three layers, namely, two electrode layers and an organic light emission layer positioned between the two electrode layers. The two electrodes are connected to a power supply. The electrode (cathode) that is in connection with a negative pole of the power supply is the electron injection layer, which generates electrons when a voltage is applied. The electrode (anode) in connection with the positive pole of the power supply is the hole injection layer, which generates holes when a voltage is applied. In such application, charge carriers (i.e., electrons and holes) are introduced into the functionalized polymer-nanoparticle composition from the anode and the cathode of the LED device. These charges are transferred from the polymer matrix to luminescent nanoparticles, which emit electromagnetic radiation (e.g., light) as electrons and holes recombine therein. When the electrons and the holes meet in the organic light emitting layer, light is generated. In the present embodiments, enhancement of the efficiency by which charge carriers are transferred from the conductive polymer matrix material to the luminescent nanoparticles is facilitated because the luminescent nanoparticles are chemically attached to the side chains of the functionalized polymer in the functionalized polymer-nanoparticle composition at selected locations in the repeating molecular structure of the polymer backbone in the functionalized polymer. The present functionalized polymer-nanoparticle composition provides a uniform distribution of nanoparticles throughout a polymer matrix.

The basic structure of the LED described above may also include an electron transport layer between the electron injection layer and the light emitting layer and a hole transport layer may be added between the hole injection layer and the light emitting layer. Furthermore, an electron-blocking layer may be added between a hole injecting layer and the light emitting layer. As used herein, the phrases “positioned between” and “disposed between” mean that the organic light emission layer lies directly between two electrode layers or lies indirectly between two electrode layers where one or more intervening layers as discussed above lie between the organic light emission layer and one or both of the electrode layers.

The functionalized polymer-nanoparticle compositions in accordance with the present embodiments may be employed as the organic light emission layer positioned between the two electrode layers in the aforementioned devices. The present compositions may be positioned or disposed between the two electrode layers. The electrode layers may be obtained by techniques known in the art. Such techniques include, by way of illustration and not limitation, thermal or e-beam evaporation, sputtering or ion beam deposition with and without reactive gaseous, argon, oxygen, nitrogen, and their mixtures. In the case of conducting electrodes using carbon nanotubes, metal nanoparticles or metal nanotubes, the electrode layers may be obtained by solution based techniques, by way of illustration and not limitation, such as spin coating, dip coating, gravure coating, screen printing and inkjet printing methods. All other layers, such as electron injection layer, electron blocking layer, electron transport layer, hole injection layer, hole blocking layer, hole transport layer and light emitting layer, which depend on their specific chemical compositions, may be processed either by vacuum processes or solution based processes as the aforementioned methods, for example. In addition, the present devices may be fabricated by sequentially laminating a first electrode, a film of the present functionalized polymer-nanoparticle composition and a second electrode onto a support. Other layers may be included in the lamination process as appropriate.

The thickness of the organic light emission layer is about 0.1 to about 500 nm, or about 1 to about 500 nm, or about 1 to about 400, or about 1 to about 300, or about 1 to about 200, or about 2 to about 500 nm, or about 2 to about 400, or about 2 to about 300, or about 2 to about 200, or about 3 to about 500 nm, or about 3 to about 400, or about 3 to about 300, or about 3 to about 200, or about 4 to about 500 nm, or about 4 to about 400, or about 4 to about 300, or about 4 to about 200, or about 5 to about 500 nm, or about 5 to about 400, or about 5 to about 300, or about 5 to about 200, or about 10 to about 500 nm, or about 10 to about 400, or about 10 to about 300, or about 10 to about 200, or about 20 to about 500, or about 20 to about 400, or about 30 to about 300, or about 50 to about 200, for example.

The light-emitting devices may additionally include one or more of a hole injecting layer, an electron injecting layer; a hole transporting layer, an electron transporting layer, an electron blocking layer, for example, as are known in the art. The devices may also include a protective layer or a sealing layer for the purpose of reducing exposure of the device to atmospheric elements. Furthermore, the devices may be one or both of covered with and packaged in an appropriate material.

The thickness of the electrodes is independently about 1 to about 1000 nm, or about 5 to about 750 nm, or about 10 to about 500 nm, or about 10 to about 400 nm, or about 10 to about 300 nm, or about 10 to about 200 nm, or about 50 to about 500 nm, or about 50 to about 400 nm, or about 50 to about 300 nm, or about 50 to about 200 nm, for example.

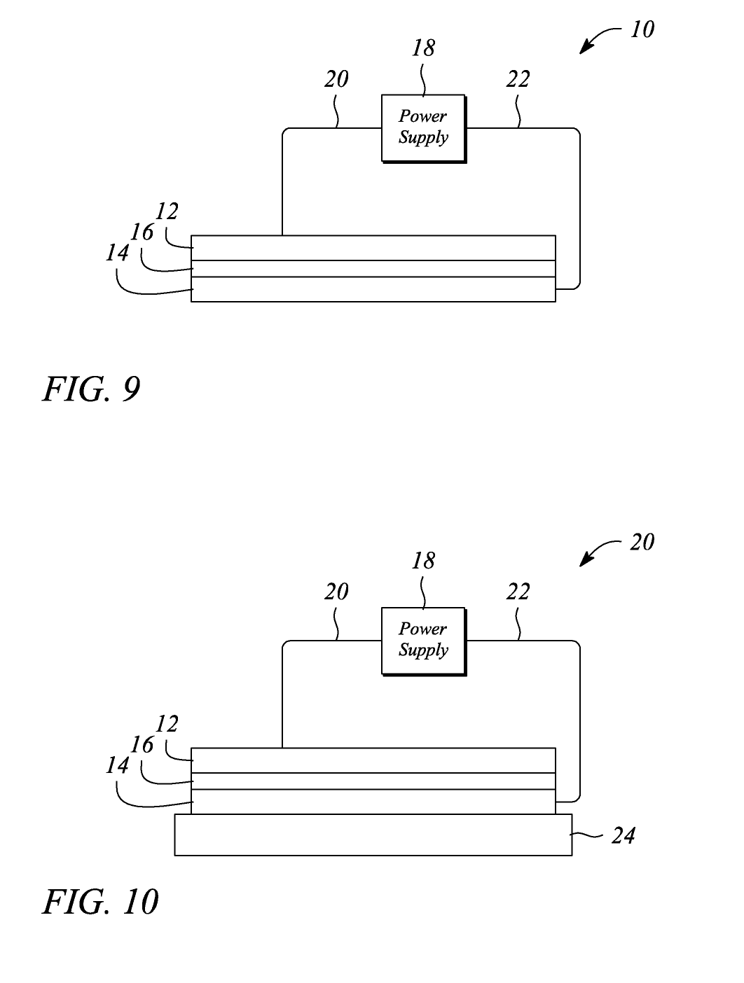

An example, by way of illustration and not limitation, of a device employing a functionalized polymer-nanoparticle composition in accordance with the present embodiments is depicted in FIG. 9. Referring to FIG. 9, light-emitting device 10 comprises first electrode 12 and second electrode 14. Disposed between electrodes 12 and 14 is layer 16 comprising a functionalized polymer-nanoparticle composition in accordance with the embodiments disclosed herein. Each of electrodes 12 and 14 is respectively connected to power supply 18 by means of lines 20 and 22. Power supply 18 is designed to separately activate electrode 12 and electrode 14.

Another example, by way of illustration and not limitation, of a device employing functionalized polymer-nanoparticle composition in accordance with the present embodiments is depicted in FIG. 10. Referring to FIG. 10, light-emitting device 20 comprises first electrode 12 and second electrode 14. Disposed between electrodes 12 and 14 is layer 16 composed of a functionalized polymer-nanoparticle composition in accordance with the embodiments disclosed herein. Each of electrodes 12 and 14 is respectively connected to power supply 18 by means of lines 20 and 22. Power supply 18 is designed to separately activate electrode 12 and electrode 14. Electrode 14 is disposed on support 24.

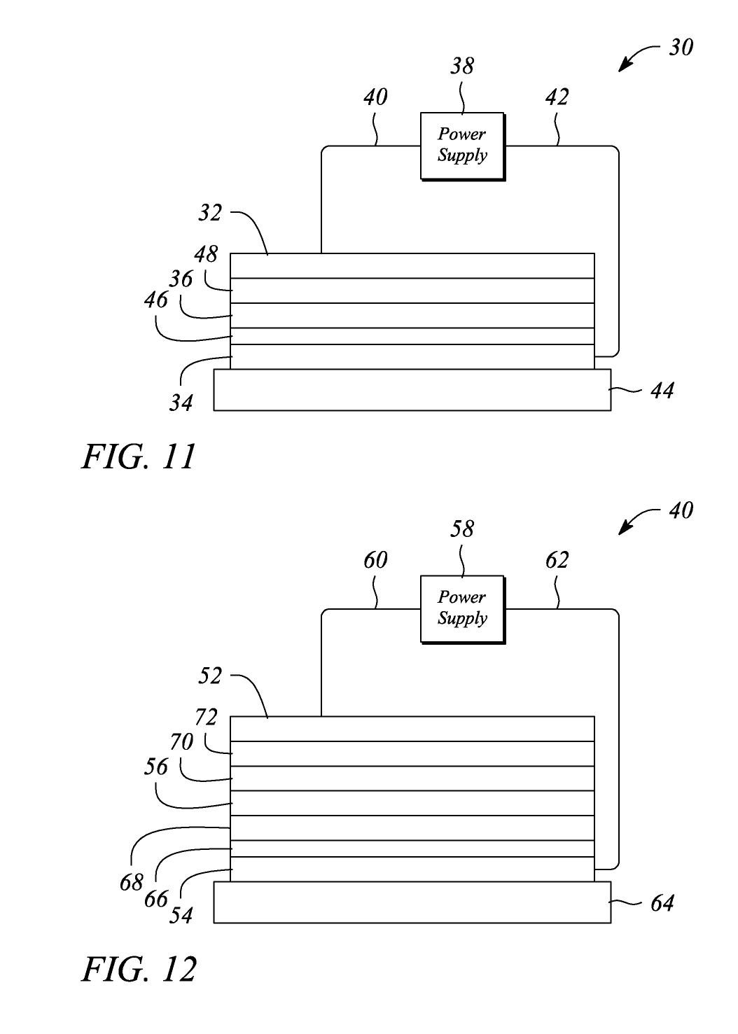

Another example, by way of illustration and not limitation, of a device employing functionalized polymer-nanoparticle composition in accordance with the present embodiments is depicted in FIG. 11. Referring to FIG. 11, light-emitting device 30 comprises first electrode 32 and second electrode 34, hole injecting layer 46, and electron injecting layer 48. Disposed between layers 46 and 48 is layer 36 comprising a functionalized polymer-nanoparticle composition in accordance with the embodiments disclosed herein. Each of electrodes 32 and 34 is respectively connected to power supply 38 by means of lines 40 and 42. Power supply 38 is designed to separately activate electrode 32 and electrode 34. Electrode 34 is disposed on support 44.

Another example, by way of illustration and not limitation, of a device employing functionalized polymer-nanoparticle composition in accordance with the present embodiments is depicted in FIG. 12. Referring to FIG. 12, light-emitting device 40 comprises first electrode 52 and second electrode 54, hole injecting layer 66, hole transporting layer 68, electron transporting layer 70 and electron injecting layer 72. Disposed between layers 68 and 70 is layer 56 comprising a functionalized polymer-nanoparticle composition in accordance with the embodiments disclosed herein. Each of electrodes 52 and 54 is respectively connected to power supply 58 by means of lines 60 and 62. Power supply 58 is designed to separately activate electrode 52 and electrode 54. Electrode 54 is disposed on support 64.

The anode may be formed from a metal such as, for example, gold, platinum, silver, copper, nickel, palladium, cobalt, molybdenum, tantalum, zirconium, vanadium, tungsten, chromium and combinations, alloys, oxides, nitrides and carbides thereof. Metal oxides include, for example, tin oxide, zinc oxide, indium oxide, indium tin oxide (ITO), and indium zinc oxide. The anode may be formed from a conductive polymer such as, for example, polyaniline, polypyrrole, polythiophene, and polyphenylene sulfide. The anode may also be formed by metallic nanoparticles, nanotubes and carbon nanotubes, for example. Each of the aforementioned materials may be used individually or in combination and the anode may be formed in a single layer construction or a multilayer construction. In a particular embodiment, the anode may be ITO.

The cathode may be formed from a metal such as, for example, lithium, sodium, potassium, calcium, cesium, magnesium, aluminum, indium, ruthenium, titanium, manganese, yttrium, silver, and alloys and nitrides, carbides, fluorides and oxides thereof. The cathode may be formed from an alloy of the aforementioned metals such as, for example, lithium-indium, sodium-potassium, magnesium-silver, aluminum-lithium, aluminum-magnesium, magnesium-indium, or a metal oxide such as, for example, indium tin oxide. Each of the aforementioned materials may be used individually or in combination. The cathode may be formed in a single layer construction or a multilayer construction. In a particular embodiment, the cathode may be aluminum.

The support may be fabricated from any suitable material for providing stability to the device and a suitable platform for the layers of the device. Such materials include, for example, glass, metals, alloys, ceramics, semiconductor material, plastic, or a combination of two or more of the above materials. The material for the support may be transparent, translucent or opaque depending on the manner in which the device is to be viewed, for example.

The hole injecting layer may be formed from any material that has a hole injecting property; such materials are known in the art and include, for example, polymer-based hole injecting chemicals such as poly(3,4-ethylenedioxythiophene), poly(styrenesulfonate) (PEDOT/PSS), poly(thiophene)-3-[2-(2-methoxyethoxy)-ethoxy]-2,5-diyl)sulfonate, and small molecules, such as tetracyanoethylene (TCNE), for example.

Materials for forming an electron injecting layer are also known in the art. Such materials include, for example, organic compounds having electron transporting properties and inorganic compounds such as, for example, certain salts of alkali metals and alkaline earth metals such as, for example, fluorides, carbonates, oxides. Specific examples include LiF, CsCO₃, and CaO.

Materials for the hole transporting layer are also known in the art and include, by way of example and not limitation, polymer-based chemicals, such as Poly[(9,9-dioctylfluoreneyl-2,7-diyl)-co-(N,N′-bis(4-butylphenyl-1,1′-biphenylene-4,4-diamine))], Poly(20vinylcarbazole), and small molecules such as N,N′-di[(1-naphthyl)-N,N′-diphenyl]-1,1′-biphenyl)-4,4′-diamine (NPD), and 4,4′-bis(N-carbazolyl)-1,1′-biphenyl (CBP), for example.

The electron transporting layer may be formed from materials that are known in the art including, for example, tris(8-hydroxyquinolinato)aluminum (Alq3), 2,9-bathocuproine (BCP), 2-phenyl-5-(4-biphenylyl)-1,3,4-oxadiazole (PBD), and 3,5-bis(4-tert-butylphenyl)-4-phenyl-4H-1,2,4-triazole (TAZ).

The electron blocking layer may be formed from a material that blocks an electron trying to move from the light emitting layer to the anode. The material may be a polymer-based compound of high or low molecular weight. The material may be a compound comprising silicon, which may be, for example, an inorganic insulator layer made of SiO₂, SiN, or an organic silicon-based polymer such as siloxane, for example.

The thickness of each of the aforementioned additional layers, when employed in a device, may be independently about 0.1 to about 500 nm, or about 1 to about 500 nm, or about 1 to about 400, or about 1 to about 300, or about 1 to about 200, or about 2 to about 500 nm, or about 2 to about 400, or about 2 to about 300, or about 2 to about 200, or about 3 to about 500 nm, or about 3 to about 400, or about 3 to about 300, or about 3 to about 200, or about 4 to about 500 nm, or about 4 to about 400, or about 4 to about 300, or about 4 to about 200, or about 5 to about 500 nm, or about 5 to about 400, or about 5 to about 300, or about 5 to about 200, or about 10 to about 500 nm, or about 10 to about 400, or about 10 to about 300, or about 10 to about 200, or about 20 to about 500, or about 20 to about 400, or about 30 to about 300, or about 50 to about 200, for example.

The present devices may also comprise a protective layer or a sealing layer for the purpose of reducing exposure of the device to atmospheric elements such as, e.g., moisture, and oxygen. Examples of materials from which a protective layer may be fabricated include inorganic films such as, for example, diamond thin films, films comprising a metal oxide or a metal nitride; polymer films such as, for example, films comprising a fluorine resin, polyparaxylene, polyethylene, a silicone resin, a polystyrene resin; and photocurable resins. In addition, the device itself may be covered with, for example, glass, a gas impermeable film, or a metal, and the device may be packaged with an appropriate sealing resin.

Additional applications of the present functionalized polymer-nanoparticle compositions include phosphors or color-conversion materials (light at one wavelength can be absorbed by either the polymer or the nanoparticles, then transferred to the other through a process such as Förster exchange, then re-radiated at a lower energy (longer wavelength)), for example.

### DEFINITIONS

The following provides definitions for terms and phrases used above, which were not previously defined.

The phrase “at least” as used herein means that the number of specified items may be equal to or greater than the number recited. The phrase “about” as used herein means that the number recited may differ by plus or minus 10%; for example, “about 5” means a range of 4.5 to 5.5. The designation “first” and “second” is used solely for the purpose of differentiating between two items such as “first electrode” and “second electrode” and is not meant to imply any sequence or order or importance to one item over another.

The term “between” when used in conjunction with two numbers such as, for example, “between about 2 and about 100” includes both of the numbers recited. Thus, the phrase “an integer between about 2 and about 100” means that the integer may be about 2 or about 100 or any integer between 2 and 100.

The term “substituted” means that a hydrogen atom of a compound or moiety is replaced by another atom such as a carbon atom or a heteroatom, which is part of a group referred to as a substituent. Substituents include, for example, alkyl, alkoxy, aryl, aryloxy, alkenyl, alkenoxy, alkynyl, alkynoxy, thioalkyl, thioalkenyl, thioalkynyl, and thioaryl, for example.

The term “heteroatom” as used herein means nitrogen, oxygen, phosphorus or sulfur. The terms “halo” and “halogen” mean a fluoro, chloro, bromo, or iodo substituent. The term “cyclic” means having an alicyclic or aromatic ring structure, which may or may not be substituted, and may or may not include one or more heteroatoms. Cyclic structures include monocyclic structures, bicyclic structures, and polycyclic structures. The term “alicyclic” is used to refer to an aliphatic cyclic moiety, as opposed to an aromatic cyclic moiety.

The phrase “aromatic ring system” or “aromatic” as used herein includes monocyclic rings, bicyclic ring systems, and polycyclic ring systems, in which the monocyclic ring, or at least a portion of the bicyclic ring system or polycyclic ring system, is aromatic (exhibits, e.g., π-conjugation). The monocyclic rings, bicyclic ring systems, and polycyclic ring systems of the aromatic ring systems may include carbocyclic rings and/or heterocyclic rings. The term “carbocyclic ring” denotes a ring in which each ring atom is carbon. The term “heterocyclic ring” denotes a ring in which at least one ring atom is not carbon and comprises 1 to 4 heteroatoms.

The term “alkyl” as used herein means a branched, unbranched, or cyclic saturated hydrocarbon group, which typically, although not necessarily, contains from 1 to about 50 carbon atoms, or 1 to about 40 carbon atoms, or 1 to about 30 carbon atoms and so forth. Alkyls include, but are not limited to, methyl, ethyl, n-propyl, isopropyl, n-butyl, isobutyl, t-butyl, octyl, and decyl, for example, as well as cycloalkyl groups such as cyclopentyl, cyclohexyl, for example. The term “lower alkyl” means an alkyl group having from 1 to 6 carbon atoms. The term “higher alkyl” means an alkyl group having more than 6 carbon atoms, for example, 7 to about 50 carbon atoms, or 7 to about 40 carbon atoms, or 7 to about 30 carbon atoms or more. As used herein, the term “substituted alkyl” means an alkyl substituted with one or more substituent groups. The term “heteroalkyl” means an alkyl in which at least one carbon atom is replaced with a heteroatom. If not otherwise indicated, the term “alkyl” includes unsubstituted alkyl, substituted alkyl, lower alkyl, and heteroalkyl.

As used herein, the term “alkenyl” means a linear, branched or cyclic hydrocarbon group of 2 to about 50 carbon atoms, or 2 to about 40 carbon atoms, or 2 to about 30 carbon atoms or more containing at least one double bond, such as ethenyl, n-propenyl, isopropenyl, n-butenyl, isobutenyl, octenyl, decenyl, tetradecenyl, hexadecenyl, eicosenyl, tetracosenyl, for example. The term “lower alkenyl” means an alkenyl having from 2 to 6 carbon atoms. The term “higher alkenyl” means an alkenyl group having more than 6 carbon atoms, for example, 7 to about 50 carbon atoms, or 7 to about 40 carbon atoms, or 7 to about 30 carbon atoms or more. The term “substituted alkenyl” means an alkenyl or cycloalkenyl substituted with one or more substituent groups. The term “heteroalkenyl” means an alkenyl or cycloalkenyl in which at least one carbon atom is replaced with a heteroatom. If not otherwise indicated, the term “alkenyl” includes unsubstituted alkenyl, substituted alkenyl, lower alkenyl, and heteroalkenyl.

As used herein, the term “alkynyl” means a linear, branched or cyclic hydrocarbon group of 2 to about 50 carbon atoms, or 2 to about 40 carbon atoms, or 2 to about 30 carbon atoms or more containing at least one triple bond, such as ethynyl, n-propynyl, isopropynyl, n-butynyl, isobutynyl, octynyl, decynyl, tetradecynyl, hexadecynyl, eicosynyl, and tetracosynyl, for example. The term “lower alkynyl” means an alkynyl having from 2 to 6 carbon atoms. The term “higher alkynyl” means an alkynyl group having more than 6 carbon atoms, for example, 7 to about 50 carbon atoms, or 7 to about 40 carbon atoms, or 7 to about 30 carbon atoms or more. The term “substituted alkynyl” means an alkynyl or cycloalkynyl substituted with one or more substituent groups. The term “heteroalkynyl” means an alkynyl or cycloalkynyl in which at least one carbon atom is replaced with a heteroatom. If not otherwise indicated, the term “alkynyl” includes unsubstituted alkynyl, substituted alkynyl, lower alkynyl, and heteroalkynyl.

The term “alkylene” as used herein means a linear, branched or cyclic alkyl group in which two hydrogen atoms are substituted at locations in the alkyl group, having 1 to about 50 carbon atoms, or 1 to about 40 carbon atoms, or 1 to about 30 carbon atoms. Alkylene linkages thus include —CH₂CH₂— and —CH₂CH₂CH₂—, for example, as well as substituted versions thereof wherein one or more hydrogen atoms are replaced with a non-hydrogen substituent. The term “lower alkylene” refers to an alkylene group containing from 2 to 6 carbon atoms. The term “higher alkylene” means an alkylene group having more than 6 carbon atoms, for example, 7 to about 50 carbon atoms, or 7 to about 40 carbon atoms, or 7 to about 30 carbon atoms or more. As used herein, the term “substituted alkylene” means an alkylene substituted with one or more substituent groups. As used herein, the term “heteroalkylene” means an alkylene wherein one or more of the methylene units are replaced with a heteroatom. If not otherwise indicated, the term “alkylene” includes heteroalkylene.

The term “alkenylene” as used herein means an alkylene containing at least one double bond, such as ethenylene (vinylene), n-propenylene, n-butenylene, n-hexenylene, for example, as well as substituted versions thereof wherein one or more hydrogen atoms are replaced with a non-hydrogen substituent, having 1 to about 50 carbon atoms, or 1 to about 40 carbon atoms, or 1 to about 30 carbon atoms. The term “lower alkenylene” refers to an alkenylene group containing from 2 to 6 carbon atoms. The term “higher alkenylene” means an alkenylene group having more than 6 carbon atoms, for example, 7 to about 50 carbon atoms, or 7 to about 40 carbon atoms, or 7 to about 30 carbon atoms or more. As used herein, the term “substituted alkenylene” means an alkenylene substituted with one or more substituent groups. As used herein, the term “heteroalkenylene” means an alkenylene wherein one or more of the alkenylene units are replaced with a heteroatom. If not otherwise indicated, the term “alkenylene” includes heteroalkenylene.

The term “alkynylene” as used herein means an alkylene containing at least one triple bond, such as ethynylene, n-propynylene, n-butynylene, and n-hexynylene, for example, having 1 to about 50 carbon atoms, or 1 to about 40 carbon atoms, or 1 to about 30 carbon atoms. The term “lower alkynylene” refers to an alkynylene group containing from 2 to 6 carbon atoms. The term “higher alkynylene” means an alkynylene group having more than 6 carbon atoms, for example, 7 to about 50 carbon atoms, or 7 to about 40 carbon atoms, or 7 to about 30 carbon atoms or more. As used herein, the term “substituted alkynylene” means an alkynylene substituted with one or more substituent groups. As used herein, the term “heteroalkynylene” means an alkynylene wherein one or more of the alkynylene units are replaced with a heteroatom. If not otherwise indicated, the term “alkynylene” includes heteroalkynylene.

The term “alkoxy” as used herein means an alkyl group bound to another chemical structure through a single, terminal ether linkage, having 1 to about 50 carbon atoms, or 1 to about 40 carbon atoms, or 1 to about 30 carbon atoms. As used herein, the term “lower alkoxy” means an alkoxy group, wherein the alkyl group contains from 1 to 6 carbon atoms, and includes, for example, methoxy, ethoxy, n-propoxy, isopropoxy, t-butyloxy. The term “higher alkoxy” means an alkoxy group wherein the alkyl group has more than 6 carbon atoms, for example, 7 to about 50 carbon atoms, or 7 to about 40 carbon atoms, or 7 to about 30 carbon atoms or more. As used herein, the term “substituted alkoxy” means an alkoxy substituted with one or more substituent groups. The term “heteroalkoxy” means an alkoxy in which at least one carbon atom is replaced with a heteroatom. If not otherwise indicated, the term “alkoxy” includes unsubstituted alkoxy, substituted alkoxy, lower alkoxy, and heteroalkoxy.

The term “alkenoxy” as used herein means an alkenyl group bound to another chemical structure through a single, terminal ether linkage, having 1 to about 50 carbon atoms, or 1 to about 40 carbon atoms, or 1 to about 30 carbon atoms. As used herein, the term “lower alkenoxy” means an alkenoxy group, wherein the alkenyl group contains from 2 to 6 carbon atoms, and includes, for example, ethenoxy, n-propenoxy, isopropenoxy, t-butenoxy. The term “higher alkenoxy” means an alkenoxy group wherein the alkenyl group has more than 6 carbon atoms, for example, 7 to about 50 carbon atoms, or 7 to about 40 carbon atoms, or 7 to about 30 carbon atoms or more. As used herein, the term “substituted alkenoxy” means an alkenoxy substituted with one or more substituent groups. The term “heteroalkenoxy” means an alkenoxy in which at least one carbon atom is replaced with a heteroatom. If not otherwise indicated, the term “alkenoxy” includes unsubstituted alkenoxy, substituted alkenoxy, lower alkenoxy, higher alkenoxy and heteroalkenoxy.

The term “alkynoxy” as used herein means an alkynyl group bound to another chemical structure through a single, terminal ether linkage, having 1 to about 50 carbon atoms, or 1 to about 40 carbon atoms, or 1 to about 30 carbon atoms. As used herein, the term “lower alkynoxy” means an alkynoxy group, wherein the alkynyl group contains from 2 to 6 carbon atoms, and includes, for example, ethynoxy, n-propynoxy, isopropynoxy, t-butynoxy. The term “higher alkynoxy” means an alkynoxy group wherein the alkynyl group has more than 6 carbon atoms, for example, 7 to about 50 carbon atoms, or 7 to about 40 carbon atoms, or 7 to about 30 carbon atoms or more. As used herein, the term “substituted alkynoxy” means an alkynoxy substituted with one or more substituent groups. The term “heteroalkynoxy” means an alkynoxy in which at least one carbon atom is replaced with a heteroatom. If not otherwise indicated, the term “alkynoxy” includes unsubstituted alkynoxy, substituted alkynoxy, lower alkynoxy, higher alkynoxy and heteroalkynoxy.

The term “thioalkyl” as used herein means an alkyl group bound to another chemical structure through a single, terminal thio (sulfur) linkage, having 1 to about 50 carbon atoms, or 1 to about 40 carbon atoms, or 1 to about 30 carbon atoms. As used herein, the term “lower thioalkyl” means a thioalkyl group, wherein the alkyl group contains from 1 to 6 carbon atoms, and includes, for example, thiomethyl, thioethyl, thiopropyl. The term “higher thioalkyl” means a thioalkyl group wherein the alkyl group has more than 6 carbon atoms, for example, 7 to about 50 carbon atoms, or 7 to about 40 carbon atoms, or 7 to about 30 carbon atoms or more. As used herein, the term “substituted thioalkyl” means a thioalkyl substituted with one or more substituent groups. The term “heterothioalkyl” means a thioalkyl in which at least one carbon atom is replaced with a heteroatom. If not otherwise indicated, the term “thioalkyl” includes unsubstituted thioalkyl, substituted thioalkyl, lower thioalkyl, and heterothioalkyl.

The term “thioalkenyl” as used herein means an alkenyl group bound to another chemical structure through a single, terminal thio (sulfur) linkage, having 1 to about 50 carbon atoms, or 1 to about 40 carbon atoms, or 1 to about 30 carbon atoms. As used herein, the term “lower thioalkenyl” means a thioalkenyl group, wherein the alkenyl group contains from 2 to 6 carbon atoms, and includes, for example, thioethenyl, thiopropenyl. The term “higher thioalkenyl” means a thioalkenyl group wherein the alkenyl group has more than 6 carbon atoms, for example, 7 to about 50 carbon atoms, or 7 to about 40 carbon atoms, or 7 to about 30 carbon atoms or more. As used herein, the term “substituted thioalkenyl” means a thioalkenyl substituted with one or more substituent groups. The term “heterothioalkenyl” means a thioalkenyl in which at least one carbon atom is replaced with a heteroatom. If not otherwise indicated, the term “thioalkenyl” includes unsubstituted thioalkenyl, substituted thioalkenyl, lower thioalkenyl, and heterothioalkenyl.

The term “thioalkynyl” as used herein means an alkynyl group bound to another chemical structure through a single, terminal thio (sulfur) linkage, having 1 to about 50 carbon atoms, or 1 to about 40 carbon atoms, or 1 to about 30 carbon atoms. As used herein, the term “lower thioalkynyl” means a thioalkynyl group, wherein the alkyl group contains from 2 to 6 carbon atoms, and includes, for example, thioethynyl, thiopropylynyl. The term “higher thioalkynyl” means a thioalkynyl group wherein the alkynyl group has more than 6 carbon atoms, for example, 7 to about 50 carbon atoms, or 7 to about 40 carbon atoms, or 7 to about 30 carbon atoms or more. As used herein, the term “substituted thioalkynyl” means a thioalkynyl substituted with one or more substituent groups. The term “heterothioalkynyl” means a thioalkynyl in which at least one carbon atom is replaced with a heteroatom. If not otherwise indicated, the term “thioalkynyl” includes unsubstituted thioalkynyl, substituted thioalkynyl, lower thioalkynyl, and heterothioalkynyl.

The term “aryl” means a group containing a single aromatic ring or multiple aromatic rings that are fused together, directly linked, or indirectly linked (such that the different aromatic rings are bound to a common group such as a methylene or ethylene moiety). Aryl groups described herein may contain, but are not limited to, from 5 to about 50 carbon atoms, or 5 to about 40 carbon atoms, or 5 to 30 carbon atoms or more. Aryl groups include, for example, phenyl, naphthyl, anthryl, phenanthryl, biphenyl, diphenylether, diphenylamine, and benzophenone. The term “substituted aryl” refers to an aryl group comprising one or more substituent groups. The term “alkylaryl” refers to aryl having one or more alkyl substituents. The term “heteroaryl” means an aryl group in which at least one carbon atom is replaced with a heteroatom. If not otherwise indicated, the term “aryl” includes unsubstituted aryl, substituted aryl, and heteroaryl.

The term “aryloxy” as used herein means an aryl group bound to another chemical structure through a single, terminal ether (oxygen) linkage, having from 5 to about 50 carbon atoms, or 5 to about 40 carbon atoms, or 5 to 30 carbon atoms or more. The term “phenoxy” as used herein is aryloxy wherein aryl is phenyl.

The term “thioaryl” as used herein means an aryl group bound to another chemical structure through a single, terminal thio (sulfur) linkage, having from 5 to about 50 carbon atoms, or 5 to about 40 carbon atoms, or 5 to 30 carbon atoms or more. The term “thiophenyl” as used herein is thioaryl wherein aryl is phenyl.

### EXAMPLES

### Materials

Unless otherwise indicated materials in the experiments below were purchased from Aldrich Chemical Company (St. Louis Mo.), Fluke Chemical Corporation (Milwaukee Wis.), Alfa Chemical Corporation (Kings Point N.Y.), Sheng Wei Te Company (Beijing, China), Ou He Company (Beijing, China), and Beijing Chemical Reagents Company (Beijing, China). Parts and percentages are by weight unless otherwise indicated.

### Example 1

2,7-dibromofluorene (XVI): To a solution of fluorene XV (30 g, 0.18 mol) and CHCl₃ (250 mL), liquid bromine (72 g, 0.45 mol) was added drop by drop under ice-bar (reaction vessel suspended in ice and stirred with a magnetic stirring bar). The reaction mixture was stirred for 24 hours (h). An aqueous solution of 50% NaOH was added to remove excess bromine. The separated organic layer was washed with brine and dried over anhydrous Na₂SO₄ and chloroform was evaporated under vacuum. The crude product was purified by recrystallization from chloroform to give a white solid XVI (55.4, 95%). ¹H NMR (300 MHz, CDCl₃, ppm): δ 7.43-7.61 (m, 6H), 3.76 (s, 2H). ¹³C NMR (75 MHz, CDCl₃, ppm): δ 144.9, 139.8, 130.3, 128.4, 121.3, 121.1, 36.7. MS m/z: 324 (M+).

### Example 2

2,7-Bibromo-9,9-bis(6′-bromohexyl)fluorene (XVII): A mixture of 2,7-dibromofluorene XVI (4.86 g, 15 mmol), 1,6-dibromohexane (30 mL), tetrabutylammonium bromine (0.1 g), and aqueous sodium hydroxide (30 mL, 50% w/w) solution was stirred overnight at 70° C. under nitrogen. After diluting the reaction mixture with chloroform, the organic layer was washed with brine and water. The separated organic layer was dried over anhydrous Na₂SO₄ and chloroform was evaporated under vacuum. Excess 1,6-dibromohexane was distilled under vacuum. 9,9-bis(6′-bromohexyl)fluorine XVII (7.3 g, 75%) was obtained as a white crystal by chromatography with petroleum ether as the eluent. ¹H NMR (300 MHz, CDCl₃, ppm): δ 7.43-7.56 (m, 6H), 3.28-3.33 (t, 4H, J=6.6 Hz), 1.89-1.95 (m, 4H), 1.24-1.70 (m, 4H), 1.22-1.25 (m, 8H), 0.53-0.63 (m, 4H). ¹³C NMR (75 MHz, CDCl₃, ppm): δ 152.3, 139.2, 130.5, 126.3, 121.7, 121.4, 55.7, 40.2, 34.1, 32.8, 29.1, 27.9, 23.6.

### Example 3

2,7-Bibromo-9,9-bis(6′-azidohexyl)fluorene (XVIII). A solution of 2,7-bibromo-9,9-bis(6′-bromohexyl)fluorine XVII (4.87 g, 7.5 mmol) and sodium azide (1.2 g, 18.8 mmol) in 40 mL of DMSO was stirred overnight at 70° C. The reaction mixture was extracted with Et₂O and H₂O. The separated organic layer was washed with brine and dried anhydrous Na₂SO₄. The diethyl ether was removed under vacuum to give a yellow oil (4.04 g, 94%). ¹H NMR (300 MHz, CDCl₃, ppm): δ 7.43-7.53 (m, 6H), 3.11-3.16 (t, 4H, J=7.2 Hz), 1.89-1.95 (t, 4H, J=8.4 Hz), 1.38-1.42 (m, 4H), 1.09-1.16 (m, 8H), 0.58-0.60 (m, 4H). ¹³C NMR (75 MHz, CDCl₃, ppm): δ 152.3, 139.2, 130.5, 126.3, 121.7, 121.4, 55.7, 51.5, 40.2, 29.5, 28.9, 26.5, 23.7. MS m/z: 574 (M⁺). HRMS: Calcd for C₂₅H₃₀Br₂N₆: 574.08782 (est.). Found: 574.00095.

### Example 4

2,7-Bibromo-9,9-bis(6′-butoxylcarbonylaminohexyl)fluorene (XIX). To a solution of 2,7-Bibromo-9,9-bis(6′-azidohexyl)fluorine XVIII (4.04 g, 7.04 mmol) in THF/H₂O (62 mL/8.4 mL), PPh₃ (4.06 g, 15.5 mmol) was added. The reaction mixture was stirred for 12 h at room temperature. The solvent was removed under vacuum and Boc-anhydride (4.11 g, 18.87 mmol) was added. The solution was stirred for 4 h at room temperature. The solvent was removed under vacuum and the residue was purified over silica gel column chromatography with petroleum ether/ethyl acetate (6:1) as the eluent to give a white solid (4.49 g, 88%). ¹H NMR (300 MHz, CDCl₃, ppm): δ 7.43-7.53 (m, 6H), 4.50 (s, 2H), 2.97-2.99 (t, 4H, J=6.3 Hz), 1.87-1.93 (t, 4H, J=8.4 Hz), 1.41 (s, 18H), 1.06-1.27 (m, 8H), 0.57 (m, 4H). ¹³C NMR (75 MHz, CDCl₃, ppm): δ 156.1, 152.5, 139.2, 130.4, 126.3, 121.7, 121.4, 79.1, 55.8, 40.6, 40.3, 30.1, 29.7, 28.6, 26.6, 23.8. MS m/z: 722 (M⁺). HRMS: Calcd for C₃₅H₅₀Br₂N₂O₄: 722.21169. Found: 722.21861.

### Example 5

2,7-Bis(4,4,5,5-tetramethyl-1,3,2-dioxaborolan-2-yl)-9,9-bis(6′-butoxylcarbonyl-aminohexyl) fluorene (XX). A mixture of 2,7-bibromo-9,9-bis(6′-butoxyl-carbonylaminohexyl)-fluorene XIX (2 g, 2.77 mmol), KOAc (1.8 g, 18.3 mmol), bis(pinacolato)diborane (1.56 g, 6.1 mmol), Pd(dppf)Cl₂ (0.16 g, 0.22 mmol) in 30 mL of degassed DMSO was stirred for 12 h at 80° C. After the mixture cooled to room temperature, water and chloroform were added to the mixture, and the separated organic layer was washed with brine and water and was dried over anhydrous Na₂SO₄. The solvent was removed under vacuum and the residue was purified over silica gel column chromatography with petroleum ether/ethyl acetate (3:1) as the eluent to give a white solid XX (1.8 g, 78%). ¹H NMR (300 MHz, CDCl₃, ppm): δ 7.70-7.82 (m, 6H), 4.43 (s, 2H), 2.94-2.96 (t, 4H, J=6 Hz), 1.96-2.01 (t, 4H, J=8.4 Hz), 1.36-1.38 (m, 42H), 1.17-1.26 (m, 4H), 1.02 (m, 8H), 0.54 (m, 4H). ¹³C NMR (75 MHz, CDCl₃, ppm): δ 156.2, 150.5, 144.1, 133.9, 129.0, 119.7, 83.9, 79.1, 55.3, 40.7, 40.2, 30.1, 29.7, 28.6, 26.5, 25.2, 23.7. Anal. Calcd for C₄₇H₇₄Br₂N₂O₈: C, 69.12; H, 9.13; N, 3.43. Found: C, 69.11; H, 9.36; N, 3.29.

### Example 6

2,7-dibromo-9,9-dihexyl-9H-fluorene (XXI). To a mixture of 2,7-dibromofluorene XVI (16.2 g, 0.05 mol), TBAB (1 g) in 300 mL of DMSO, aqueous NaOH (10 ml, 50% w/w) was added under ice-bar and stirred for 20 min, and then 1-bromohexane (18.2 g, 0.11 mol) was added. The reaction mixture was stirred at room temperature for 24 h. After diluting the reaction mixture with chloroform, the organic layer was washed with brine and water. The separated organic layer was dried over anhydrous Na₂SO₄ and chloroform was evaporated under vacuum. The residue was purified by chromatography with petroleum ether as the eluent to give a white crystal XXI (21.6 g, 88%). ¹H NMR (300 MHz, CDCl₃, ppm): δ 7.43-7.53 (m, 6H), 1.88-1.94 (m, 4H), 1.03-1.13 (m, 12H), 0.75-0.80 (t, 6H, J=6.9 Hz), 0.58-0.61 (m, 4H).

### Example 7

2-(9,9-dihexyl-2-(4,4,5,5-tetramethyl-1,3,2-dioxaborolan-2-yl)-9H-fluoren-7-yl)-4,4,5,5-tetramethyl-1,3,2-dioxaborolane (XXII). A mixture of 2,7-dibromo-9,9-dihexyl-9H-fluorene XXI (15 g, 30.5 mmol), KOAc (18 g, 183 mmol), bis(pinacolato)diborane (16.4 g, 64 mmol), Pd(dppf)Cl₂ (1.8 g, 0.22 mmol) in 150 mL of degassed 1,4-dioxane was stirred for 12 h at 80° C. After the mixture cooled to room temperature, water and chloroform were added into the mixture, and the separated organic layer was washed with brine and water and was dried over anhydrous Na₂SO₄. The solvent was removed under vacuum and the residue was purified over silica gel column chromatography with petroleum as the eluent to give a white solid XXII (13.4 g, 75%). ¹H NMR (300 MHz, CDCl₃, ppm): δ 7.70-7.81 (m, 6H), 1.39 (s, 24H), 1.01-1.11 (m, 12H), 0.72-0.76 ((t, 6H, J=6.9 Hz).

The following examples (Examples 8-12) show the preparation of functionalized polymer XXIII wherein the molar concentrations of the monomer units is varied to produce m:n ratios of 1:39, 1:19, 1:9, 3:17 and 1:4, respectively.

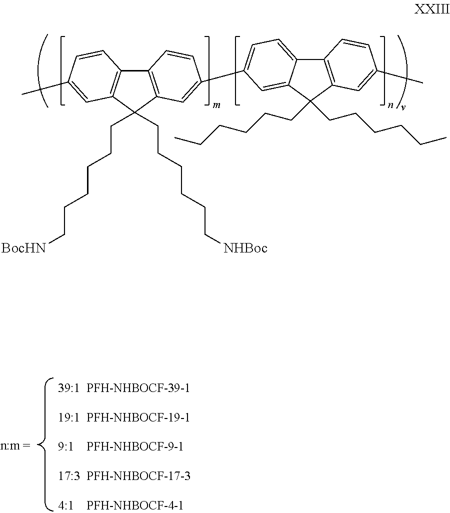

### Example 8

XXIII PFH—NHBOCF-39-1. A mixture of XIX (36.1 mg, 0.05 mmol), XXII (586 mg, 1 mmol), XXI (467 mg, 0.95 mmol), Pd(PPh₃)₄ (24 mg, 0.02 mmol), 2-3 drops ALIQUAT 336®, and 1.66 g K₂CO₃ was added into a two-neck flask and degassed by N₂. Then, degassed toluene (11 mL) and deionized water (6 mL) were injected by syringe. The reaction mixture was stirred under nitrogen purge at 95° C. for 48 h. After cooling to room temperature, water and chloroform were added, the separated organic layer was washed with brine and water and was dried over anhydrous Na₂SO₄. Most of the chloroform was evaporated under vacuum. The residue was added to stirred methanol to give a precipitate. The precipitate was dissolved in chloroform and purified over a short silica gel column chromatography to remove Pd and reprecipitated from methanol to give a white solid XXIII PFH—NHBOCF-39-1 (540 mg, 80%). ¹H NMR (300 MHz, CDCl₃, ppm): δ 7.47-7.86 (m, 8H), 3.37-3.40 (m, 0.27H), 3.31 (m, 0.12H), 2.12 (m, 4H), 1.82 (m, 0.88H), 1.41 (m, 1H), 0.59-1.25 (m, 40H). ¹³C NMR (50 MHz, CDCl₃, ppm): δ 152.1, 140.8, 140.3, 126.5, 121.8, 120.3, 55.5, 40.6, 31.6, 29.9, 24.0, 22.75, 22.7, 14.2, 14.1. IR (cm⁻¹): 2956, 2926, 2850, 1717, 1458, 1437, 1260, 1095, 1022, 812. Anal. Calcd: C, 89.38; H, 10.22; N, 0.12. Found: C, 87.29; H, 10.26; N, 0.32.

### Example 9

XXIII PFH—NHBOCF-19-1. A mixture of XIX (72.2 mg, 0.1 mmol), XXII (586 mg, 1 mmol), XXI (443 mg, 0.9 mmol), Pd(PPh₃)₄ (24 mg, 0.02 mmol), 2-3 drop ALIQUAT 336®, 1.66 g K₂CO₃ was added into a two-neck flask and degassed by N₂. Then, degassed toluene (11 mL) and deionized water (6 mL) were injected by syringe. The reaction mixture was stirred under nitrogen purge at 95° C. for 48 h. After cooling to room temperature, water and chloroform were added, the separated organic layer was washed with brine and water and was dried over anhydrous Na₂SO₄. Most of the chloroform was evaporated under vacuum. The residue was added to stirred methanol to give a precipitate. The precipitate was dissolved in chloroform and purified over a short silica gel column chromatography to remove Pd and reprecipitated from methanol to give a white solid XXIII PFH—NHBOCF-19-1 (566 mg, 82%). ¹H NMR (300 MHz, CDCl₃, ppm): δ 7.30-7.86 (m, 8H), 3.39-3.44 (m, 0.37H), 3.31 (m, 0.15H), 2.99 (m, 0.11H), 2.12 (m, 4H), 1.82 (m, 0.88H), 1.41 (m, 2H), 0.59-1.35 (m, 32H). ¹³C NMR (50 MHz, CDCl₃, ppm): δ 152.1, 140.8, 140.3, 126.5, 121.8, 120.3, 55.5, 40.5, 31.8, 31.6, 29.8, 29.5, 29.4, 29.3, 28.6, 26.5, 24.0, 22.7, 14.2, 14.1. IR (cm⁻¹): 2957, 2928, 2850, 1723, 1458, 1260, 1093, 1068, 910, 813, 802. Anal. Calcd: C, 88.99; H, 10.19; N, 0.25. Found: C, 86.74; H, 10.14; N, 0.51.

### Example 10

XXIII PFH—NHBOCF-9-1. A mixture of XIX (144 mg, 0.2 mmol), XXII (586 mg, 1 mmol), XXI (394 mg, 0.8 mmol), Pd(PPh₃)₄ (24 mg, 0.02 mmol), 2-3 drop ALIQUAT 336®, 1.66 g K₂CO₃ was added into a two-neck flask and degassed by N₂; then, degassed toluene (11 mL) and deionized water (6 mL) were injected by syringe. The reaction mixture was stirred under nitrogen purge at 95° C. for 48 h. After cooling to room temperature, water and chloroform were added, the separated organic layer was washed with brine and water and was dried over anhydrous Na₂SO₄ and most of the chloroform was evaporated under vacuum. The residue was added to stirred methanol to give a precipitate. The precipitate was dissolved in chloroform and purified over a short silica gel column chromatography to remove Pd and reprecipitated from methanol to give a yellow solid XXIII PFH—NHBOCF-9-1 (556 mg, 78%). ¹H NMR (300 MHz, CDCl₃, ppm): δ 7.34-7.86 (m, 10H), 3.38 (m, 0.06H), 2.99 (m, 0.3H), 2.12 (m, 4H), 1.41 (m, 3H), 0.59-1.26 (m, 40H). ¹³C NMR (75 MHz, CDCl₃, ppm): δ 156.1, 152.5, 152.0, 151.8, 140.8, 140.2, 132.4, 132.3, 132.1, 128.9, 128.7, 128.6, 127.4, 126.4, 121.8, 121.0, 120.2, 79.2, 61.7, 55.6, 40.5, 32.1, 32.0, 31.8, 31.7, 30.2, 29.9, 29.6, 29.5, 29.4, 29.3, 29.2, 28.6, 26.8, 26.5, 24.1, 22.8, 14.3, 14.2. IR (cm⁻¹): 2954, 2918, 2849, 1723, 1458, 1438, 1402, 1260, 1093, 1069, 1020, 951, 813. Anal. Calcd: C, 88.23; H, 10.14; N, 0.50. Found: C, 86.56; H, 10.01; N, 0.63.

### Example 11

XXIII PFH—NHBOCF-17-3. A mixture of XIX (217 mg, 0.3 mmol), XXII (586 mg, 1 mmol), XXI (344 mg, 0.7 mmol), Pd(PPh₃)₄ (24 mg, 0.02 mmol), 2-3 drop ALIQUAT 336®, 1.66 g K₂CO₃ was added into a two-neck flask and degassed by N₂, and then degassed toluene (11 mL) and deionized water (6 mL) were injected by syringe. The reaction mixture was stirred under nitrogen purge at 95° C. for 48 h. After cooling to room temperature, water and chloroform were added, the separated organic layer was washed with brine and water and was dried over anhydrous Na₂SO₄; most of the chloroform was evaporated under vacuum. The residue was added to stirred methanol to give a precipitate. The precipitate was dissolved in chloroform and purified over a short silica gel column chromatography to remove Pd and reprecipitated from methanol to give a yellow solid XXIII PFH—NHBOCF-17-3 (v=3 wherein m=1, n=5 in first co-block; m=1, n=6 in second co-block; m=1, n=6 is third co-block) (475 mg, 65%). ¹H NMR (300 MHz, CDCl₃, ppm): δ 7.47-7.86 (m, 14H), 4.39 (m, 0.40H), 2.99-3.01 (m, 1.28H), 2.05-2.12 (m, 8H), 1.41 (m, 7H), 0.59-1.26 (m, 47H). ¹³C NMR (75 MHz, CDCl₃, ppm): δ 156.1, 152.0, 151.8, 140.8, 140.3, 132.4, 132.3, 129.0, 128.7, 127.4, 126.4, 121.8, 120.2, 79.2, 55.6, 40.6, 31.7, 30.2, 29.9, 28.6, 26.8, 24.1, 22.8, 14.3, 14.2. IR (cm⁻¹): 2926, 2849, 1709, 1458, 1260, 1172, 1099, 1069, 1014, 813. Anal. Calcd: C, 87.46; H, 10.09; N, 0.74. Found: C, 86.29; H, 9.79; N, 0.85.

### Example 12

XXIII PFH—NHBOCF-4-1. A mixture of XIX (289 mg, 0.4 mmol), XXII (586 mg, 1 mmol), XXI (295 mg, 0.6 mmol), Pd(PPh₃)₄ (24 mg, 0.02 mmol), 2-3 drop ALIQUAT 336®, 1.66 g K₂CO₃ was added into a two-neck flask and degassed by N₂. Then degassed toluene (11 mL) and deionized water (6 mL) were injected by syringe. The reaction mixture was stirred under nitrogen purge at 95° C. for 48 h. After cooling to room temperature, water and chloroform were added. The separated organic layer was washed with brine and water and was dried over anhydrous Na₂SO₄. Most of the chloroform was evaporated under vacuum. The residue was added to stirred methanol to give a precipitate. The precipitate was dissolved in chloroform and purified over a short silica gel column chromatography to remove Pd and reprecipitated from methanol to give a yellow solid XXIII PFH—NHBOCF-4-1 (510 mg, 67%). ¹H NMR (300 MHz, CDCl₃, ppm): δ 7.34-7.86 (m, 14H), 4.39 (m, 0.40H), 3.29-3.38 (m, 0.3H), 2.99-3.01 (m, 1.38H), 2.12 (m, 8H), 1.41 (m, 10H), 0.59-1.26 (m, 50H). ¹³C NMR (75 MHz, CDCl₃, ppm): δ 156.1, 152.0, 151.8, 140.8, 140.6, 140.2, 132.4, 132.3, 128.9, 128.7, 127.4, 126.4, 121.7, 120.2, 79.1, 61.8, 55.5, 40.6, 32.9, 32.1, 31.8, 31.7, 30.2, 29.9, 29.6, 29.3, 29.2, 28.6, 26.8, 26.5, 24.0, 22.9, 22.8, 14.2. IR (cm⁻¹): 2958, 2927, 2855, 1715, 1504, 1458, 1260, 1172, 1095, 1021, 812. Anal. Calcd: C, 86.69; H, 10.05; N, 0.99. Found: C, 85.06; H, 9.88; N, 1.19.

The following examples (Examples 13-17) show the preparation of functionalized polymer XXIV wherein the molar concentrations of the monomer units were varied to produce m:n ratios of 1:39, 1:19, 1:9, 3:17 and 1:4, respectively.

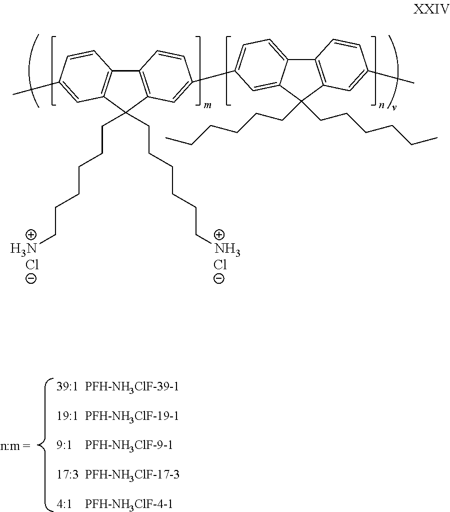

### Example 13

XXIV PFH—NH₃ClF-39-1. To a solution of PFH—NHBocF-39-1 (130 mg) in 15 mL THF, 5 mL 37% hydrochloric acid was added. The reaction mixture was stirred 3 days at room temperature. Solvent was evaporated under vacuum, and 50 mL acetone was added to give a precipitate, which was filtered to give a yellow powder XXIV PFH—NH₃ClF-39-1 (105 mg, 82%). ¹H NMR (300 MHz, CDCl₃, ppm): δ 7.59-7.86 (m, 11H), 2.12 (m, 4H), 0.77-1.25 (m, 44H). IR (cm⁻¹): 3439, 2922, 2852, 1641, 1453, 1249, 810.

### Example 14

XXIV PFH—NH₃ClF-19-1. To a solution of PFH—NHBocF-19-1 (130 mg) in 15 mL THF, 5 mL 37% hydrochloric acid was added, and the reaction mixture was stirred 3 days at room temperature. Solvent was evaporated under vacuum, and 50 mL acetone was added to give a precipitate, which was filtered to give a yellow powder XXIV PFH—NH₃ClF-19-1 (103 mg, 81%). ¹H NMR (300 MHz, CDCl₃, ppm): δ 7.61-7.86 (m, 18H), 2.12 (m, 4H), 0.77-1.25 (m, 50H). IR (cm⁻¹): 3432, 2923, 2853, 1638, 1455, 1250, 811.

### Example 15

XXIV PFH—NH₃ClF-9-1. To a solution of PFH—NHBocF-9-1 (130 mg) in 15 mL THF, 5 mL 37% hydrochloric acid was added. The reaction mixture was stirred 3 days at room temperature. Solvent was evaporated under vacuum, and 50 mL acetone was added to give a precipitate, which was filtered to give a yellow powder XXIV PFH—NH₃ClF-9-1 (98 mg, 78%). IR (cm⁻¹): 3441, 2923, 2852, 1642, 1454, 1248, 810.

### Example 16

XXIV PFH—NH₃Cl-17-3. To a solution of PFH—NHBocF-17-3 (130 mg) in 15 mL THF, 5 mL 37% hydrochloric acid was added, and the reaction mixture was stirred 3 days at room temperature. Solvent was evaporated under vacuum, and 50 mL acetone was added to give a precipitate, which was filtered to give a yellow powder XXIV PFH—NH₃Cl-17-3 (v=3 wherein m=1, n=5 in first co-block; m=1, n=6 in second co-block; m=1, n=6 is third co-block) (85 mg, 69%). IR (cm⁻¹): 3448, 2924, 2854, 1636, 1455, 1252, 811.

### Example 17

XXIV PFH—NH₃Cl-4-1. To a solution of PFH—NHBocF-4-1 (130 mg) in 15 mL THF, 5 mL 37% hydrochloric acid was added, and the reaction mixture was stirred 3 days at room temperature. Solvent was evaporated under vacuum, and 50 mL acetone was added to give a precipitate, which was filtered to give a yellow powder XXIV PFH—NH₃Cl-4-1 (82 mg, 68%). IR (cm⁻¹): 3450, 2923, 2853, 1639, 1455, 1252, 810.

The following examples (Examples 18-22) show the preparation of functionalized polymer XXV wherein the molar concentrations of the monomer units were varied to produce m:n ratios of 1:39, 1:19, 1:9, 3:17 and 1:4, respectively.

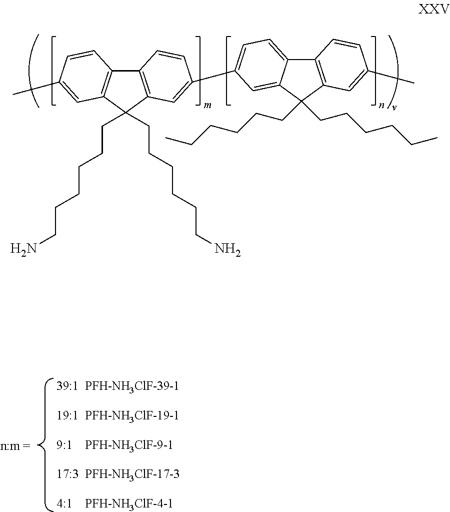

### Example 18

XXV PFH—NH₂F-39-1. To a solution of PFH—NH₃ClF-39-1 (100 mg) in 30 mL CHCl₃, was added 20 mL 50% KOH aqueous solution. The reaction mixture was stirred at room temperature for 1 h. The separated organic layer was washed with water, and solvent was evaporated under vacuum. 50 mL acetone was added to give a precipitate, and the precipitate was filtered to give a yellow powder XXV PFH—NH₂F-39-1 (75 mg, 77%). IR (cm⁻¹): 3448, 2923, 2855, 1641, 1453, 1250, 811.

### Example 19

XXV PFH—NH₂F-19-1. To a solution of PFH—NH₃ClF-19-1 (100 mg) in 50 mL CHCl₃, was added 20 mL 50% KOH aqueous solution. The reaction mixture was stirred at room temperature for 1 h. The separated organic layer was washed with water, and solvent was evaporated under vacuum. 50 mL acetone was added to give a precipitate, and the precipitate was filtered to give a yellow powder XXV PFH—NH₂F-19-1 (72 mg, 74%). IR (cm⁻¹): 3450, 2924, 2854, 1641, 1455, 1250, 811.

### Example 20

XXV PFH—NH. To a solution of PFH—NH₃ClF-9-1 (100 mg) in 100 mL CHCl₃, was added 20 mL 50% KOH aqueous solution, and the reaction mixture was stirred at room temperature for 1 h. The separated organic layer was washed with water, and solvent was evaporated under vacuum. 50 mL acetone was added to give a precipitate, and the precipitate was filtered to give a yellow powder XXV PFH—NH₂F-9-1 (68 mg, 72%). IR (cm⁻¹): 3445, 2924, 2854, 1690, 1455, 1249, 813.

### Example 21

XXV PFH—NH₂F-17-3. To a solution of PFH—NH₃ClF-17-3 (100 mg) in 100 mL CHCl₃, was added 20 mL 50% KOH aqueous solution. The reaction mixture was stirred at room temperature for 1 h. and the separated organic layer was washed with water. Solvent was evaporated under vacuum. 50 mL acetone was added to give a precipitate, and the precipitate was filtered to give a yellow powder XXV PFH—NH₂F-17-3 (v=3 wherein m=1, n=5 in first co-block; m=1, n=6 in second co-block; m=1, n=6 is third co-block) (67 mg, 73%). IR (cm⁻¹): 3452, 2926, 2855, 1636, 1451, 812.

### Example 22

XXV PFH—NH₂F-4-1. To a solution of PFH—NH₃ClF-4-1 (100 mg) in 100 mL CHCl₃, was added 20 mL 50% KOH aqueous solution. Then, the reaction mixture was stirred at room temperature for 1 h. and the separated organic layer was washed with water. Solvent was evaporated under vacuum. 50 mL acetone was added to give a precipitate, and the precipitate was filtered to give a yellow powder XXV PFH—NH₂F-4-1 (58 mg, 65%). IR (cm⁻¹): 3444, 2926, 2856, 1635, 1444, 881, 812.

Although the foregoing invention has been described in some detail by way of illustration and example for purposes of clarity of understanding, it will be readily apparent to those of ordinary skill in the art in light of the teachings of this invention that certain changes and modifications may be made thereto without departing from the spirit or scope of the appended claims. Furthermore, the foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description; they are not intended to be exhaustive or to limit the invention to the precise forms disclosed. Many modifications and variations are possible in view of the above teachings. The embodiments were chosen and described in order to explain the principles of the invention and its practical applications and to thereby enable others skilled in the art to utilize the invention.

What is claimed is:

1. A polymer comprising repeating monomer units having the formula: 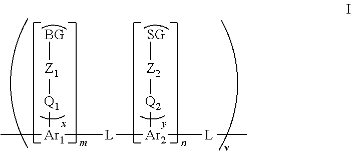
wherein:
BG is a binding group for binding to a nanoparticle,
Z₁ and Z₂ are independently a covalent bond or a chemical moiety, wherein Z₁ provides a covalent bond between BG and Q₁, and Z₂ provides a covalent bond between SG and Q₂,
Q₁ and Q₂ are independently a carbon atom or a heteroatom,
Ar₁ and Ar₂ are independently an aromatic ring moiety,
L is independently a covalent bond directly linking Ar₁ and Ar₂ or a chemical moiety linking Ar₁ and Ar₂,
m and n are integers independently between 1 and about 5,000,
v is an integer greater than about 10,
x and y are integers independently between 1 and about 5, and
SG is a hydrophobic moiety, with the proviso that if m is 1, then SG comprises at least 25 carbon atoms.

2. The polymer of claim 1 wherein:
BG is selected from the group consisting of primary amines, secondary amines, tertiary amines, amides, nitriles, isonitriles, cyanates, isocyanates, thiocyanates, isothiocyanates, azides, thiols, thiolates, sulfides, sulfinates, sulfonates, phosphates, hydroxyls, alcoholates, phenolates, carbonyls, carboxylates, phosphines, phosphine oxides, phosphonic acids, phosphoramides and phosphates;
SG is selected from the group consisting of alkyl of about 5 to about 50 carbon atoms, substituted alkyl of about 5 to about 50 carbon atoms, alkoxy of about 5 to about 50 carbon atoms, substituted alkoxy of about 5 to about 50 carbon atoms, thioalkyl of about 5 to about 50 carbon atoms, substituted thioalkyl of about 5 to about 50 carbon atoms, alkenyl of about 5 to about 50 carbon atoms, substituted alkenyl of about 5 to about 50 carbon atoms, alkenoxy of about 5 to about 50 carbon atoms, substituted alkenoxy of about 5 to about 50 carbon atoms, thioalkenyl of about 5 to about 50 carbon atoms, substituted thioalkenyl of about 5 to about 50 carbon atoms, alkynyl of about 5 to about 50 carbon atoms, substituted alkynyl of about 5 to about 50 carbon atoms, alkynoxy of about 5 to about 50 carbon atoms, substituted alkynoxy of about 5 to about 50 carbon atoms, thioalkynyl of about 5 to about 50 carbon atoms, substituted thioalkynyl of about 5 to about 50 carbon atoms, aryl of about 5 to about 50 carbon atoms, substituted aryl of about 5 to about 50 carbon atoms, aryloxy of about 5 to about 50 carbon atoms, substituted aryloxy of about 5 to about 50 carbon atoms, thioaryl of about 5 to about 50 carbon atoms, substituted thioaryl of about 5 to about 50 carbon atoms, alkylaryl of about 5 to about 50 carbon atoms, and including counterparts thereof comprising one or more heteroatoms;
L is independently a covalent bond directly linking Ar₁ and Ar₂ or a linking group selected from the group consisting of: 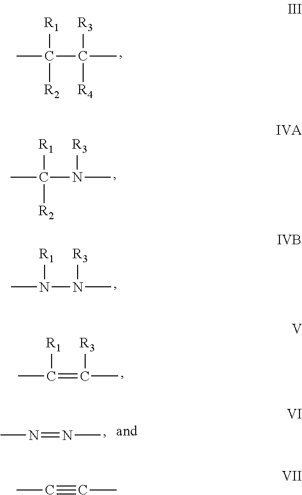
wherein:
R₁, R₂, R₃, R₄ are each independently selected from the group consisting of hydrogen, alkyl, substituted alkyl, heteroalkyl, alkyl, substituted alkenyl, heteroalkenyl, alkynyl, substituted alkynyl, heteroalkynyl, aryl, substituted aryl, heteroaryl;
Z₁ provides a covalent bond between BG and Q₁, and is independently selected from the group consisting of a covalent bond and a chemical moiety selected from the group consisting of alkylene of 1 to about 30 carbon atoms, substituted alkylene of 1 to about 30 carbon atoms, alkylenoxy of 1 to about 30 carbon atoms, substituted alkylenoxy of 1 to about 30 carbon atoms, thioalkylene of 1 to about 30 carbon atoms, substituted thioalkylene of 1 to about 30 carbon atoms, alkenylene of 1 to about 30 carbon atoms, substituted alkenylene of 1 to about 30 carbon atoms, alkenylenoxy of 1 to about 30 carbon atoms, substituted alkenylenoxy of 1 to about 30 carbon atoms, thioalkenylene of 1 to about 30 carbon atoms, substituted thioalkenylene of 1 to about 30 carbon atoms, alkynylene of 1 to about 30 carbon atoms, substituted alkynylene of 1 to about 30 carbon atoms, alkynylenoxy of 1 to about 30 carbon atoms, substituted alkynylenoxy of 1 to about 30 carbon atoms, thioalkynylene of 1 to about 30 carbon atoms, substituted thioalkynylene of 1 to about 30 carbon atoms, arylene of 1 to about 30 carbon atoms, substituted arylene of 1 to about 30 carbon atoms, arylenoxy of 1 to about 30 carbon atoms, thioarylene of 1 to about 30 carbon atoms, and counterparts of the above comprising one or more heteroatoms;
Z₂ provides a covalent bond between SG and Q₂, and is independently selected from the group consisting of a covalent bond and a chemical moiety selected from the group consisting of alkylene of 1 to about 30 carbon atoms, substituted alkylene of 1 to about 30 carbon atoms, alkylenoxy of 1 to about 30 carbon atoms, substituted alkylenoxy of 1 to about 30 carbon atoms, thioalkylene of 1 to about 30 carbon atoms, substituted thioalkylene of 1 to about 30 carbon atoms, alkenylene of 1 to about 30 carbon atoms, substituted alkenylene of 1 to about 30 carbon atoms, alkenylenoxy of 1 to about 30 carbon atoms, substituted alkenylenoxy of 1 to about 30 carbon atoms, thioalkenylene of 1 to about 30 carbon atoms, substituted thioalkenylene of 1 to about 30 carbon atoms, alkynylene of 1 to about 30 carbon atoms, substituted alkynylene of 1 to about 30 carbon atoms, alkynylenoxy of 1 to about 30 carbon atoms, substituted alkynylenoxy of 1 to about 30 carbon atoms, thioalkynylene of 1 to about 30 carbon atoms, substituted thioalkynylene of 1 to about 30 carbon atoms, arylene of 1 to about 30 carbon atoms, substituted arylene of 1 to about 30 carbon atoms, arylenoxy of 1 to about 30 carbon atoms, thioarylene of 1 to about 30 carbon atoms, and counterparts of the above comprising one or more heteroatoms; and
Ar₁ and Ar₂ are each independently selected from the group consisting of phenyl, fluorenyl, biphenyl, terphenyl, tetraphenyl, naphthyl, anthryl, pyrenyl, phenanthryl, thiophenyl, pyrrolyl, furanyl, imidazolyl, triazolyl, isoxazolyl, oxazolyl, oxadiazolyl, furazanyl, pyridyl, bipyridyl, pyridazinyl, pyrimidyl, pyrazinyl, triazinyl, tetrazinyl, benzofuranyl, benzothiophenyl, indolyl, isoindazolyl, benzimidazolyl, benzotriazolyl, benzoxazolyl, quinolyl, isoquinolyl, cinnolyl, quinazolyl, naphthyridyl, phthalazyl, phentriazyl, benzotetrazyl, carbazolyl, dibenzofuranyl, dibenzothiophenyl, acridyl, and phenazyl.

3. The polymer of claim 1, wherein one or more BG groups are bound to the nanoparticle, and wherein SG facilitates steric stabilization and homogeneity of mixtures of the nanoparticle in a non-polar medium.

4. The polymer of claim 1, wherein the nanoparticle comprises an element selected from the group consisting of Group 2 elements, Group 12 elements, Group 13 elements, Group 3 elements, Group 14 elements, Group 4 elements, Group 15 elements, Group 5 elements, Group 16 elements and Group 6 elements and combinations of elements from one or more of the aforementioned groups.

5. The polymer of claim 1 comprising repeating monomer units having the formula: 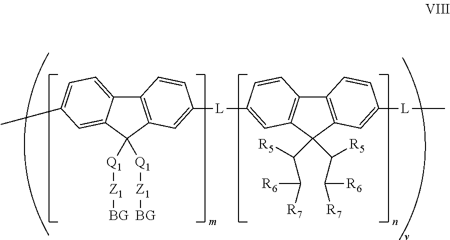
wherein:
BG is independently selected from the group consisting of primary amines, secondary amines, tertiary amines, amides, nitriles, isonitriles, cyanates, isocyanates, thiocyanates, isothiocyanates, azides, thiols, thiolates, sulfides, sulfinates, sulfonates, phosphates, hydroxyls, alcoholates, phenolates, carbonyls, carboxylates, phosphines, phosphine oxides, phosphonic acids, phosphoramides and phosphates,
L is independently a covalent bond directly linking Ar₁ and Ar₂ or a linking group selected from the group consisting of: 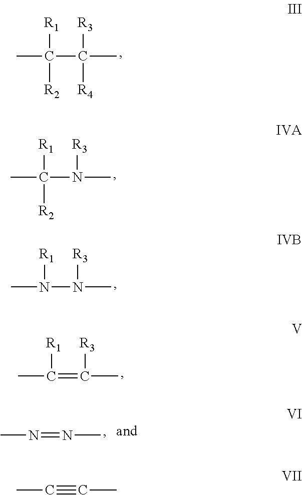
wherein R₁, R₂, R₃, R₄ are each independently selected from the group consisting of hydrogen, alkyl, substituted alkyl, heteroalkyl, alkyl, substituted alkenyl, heteroalkenyl, alkynyl, substituted alkynyl, heteroalkynyl, aryl, substituted aryl, heteroaryl,
each R₅ is independently selected from the group consisting of hydrogen, alkyl, substituted alkyl, heteroalkyl, alkyl, substituted alkenyl, heteroalkenyl, alkynyl, substituted alkynyl, heteroalkynyl, aryl, substituted aryl, heteroaryl,
each R₆ is independently selected from the group consisting of hydrogen, alkyl, substituted alkyl, heteroalkyl, alkyl, substituted alkenyl, heteroalkenyl, alkynyl, substituted alkynyl, heteroalkynyl, aryl, substituted aryl, heteroaryl, and
each R₇ is independently selected from the group consisting of alkyl of about 5 to about 50 carbon atoms, substituted alkyl of about 5 to about 50 carbon atoms, alkenyl of about 5 to about 50 carbon atoms, substituted alkenyl of about 5 to about 50 carbon atoms, alkynyl of about 5 to about 50 carbon atoms, substituted alkynyl of about 5 to about 50 carbon atoms, alkoxy of about 5 to about 50 carbon atoms, substituted alkoxy of about 5 to about 50 carbon atoms, alkenoxy of about 5 to about 50 carbon atoms, substituted alkenoxy of about 5 to about 50 carbon atoms, alkynoxy of about 5 to about 50 carbon atoms, substituted alkynoxy of about 5 to about 50 carbon atoms, thioalkyl of about 5 to about 50 carbon atoms, substituted thioalkyl of about 5 to about 50 carbon atoms, aryl of about 5 to about 50 carbon atoms, aryloxy of about 5 to about 50 carbon atoms, thioaryl of about 5 to about 50 carbon atoms, alkylaryl of about 5 to about 50 carbon atoms, and corresponding substituted counterparts and heteroatom counterparts thereof, with the proviso that, if m is 1, then at least one R₇ comprises at least 25 carbon atoms.

6. A polymer-nanoparticle composition comprising the polymer of claim 1 and the nanoparticle, wherein one or more BG groups are bound to the nanoparticle, and wherein the polymer enhances stabilization and homogeneity of mixtures of the polymer-nanoparticle composition in a non-polar medium.

7. A polymer-nanoparticle composition having the formula: 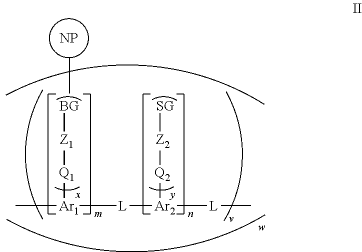
wherein:
BG is a binding group that is bound to a nanoparticle,
Z₁ and Z₂ are independently a covalent bond or a chemical moiety, wherein Z₁ provides a covalent bond between BG and Q₁, and Z₂ provides a covalent bond between SG and Q₂,
Q₁ and Q₂ are independently a carbon atom or a heteroatom,
Ar₁ and Ar₂ are independently an aromatic ring moiety,
L is independently a covalent bond directly linking Ar₁ and Ar₂ or a chemical moiety linking Ar₁ and Ar₂,
w is an integer between about 2 and about 100,
m and n are integers independently between 1 and about 5,000,
v is an integer greater than about 10,
x and y are integers independently between 1 and about 5,
SG is a hydrophobic moiety, with the proviso that if m is 1, then SG comprises at least 25 carbon atoms, and
NP is the nanoparticle.

8. The polymer-nanoparticle composition of claim 7 dispersed in a non-polar medium, wherein SG facilitates steric stabilization and homogeneity of mixtures of the nanoparticle in the non-polar medium.

9. A light-emitting device comprising the polymer-nanoparticle composition of claim 7.

10. The device of claim 9, wherein the polymer-nanoparticle composition is in the form of a layer disposed between two electrodes.

11. A light emitting device comprising:
(a) a first electrode,
(b) a second electrode, and
(c) a polymer-nanoparticle composition disposed between the first electrode and the second electrode wherein the polymer-nanoparticle composition has the formula: 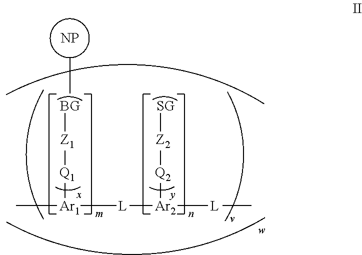
wherein:
BG is a binding group for binding to a nanoparticle,
Z₁ and Z₂ are independently a covalent bond or a chemical moiety, wherein Z₁ provides a covalent bond between BG and Q₁, and Z₂ provides a covalent bond between SG and Q₂,
Q₁ and Q₂ are independently a carbon atom or a heteroatom,
Ar₁ and Ar₂ are independently an aromatic ring moiety,
L is independently a covalent bond directly linking Ar₁ and Ar₂ or a chemical moiety linking Ar₁ and Ar₂,
w is an integer between about 2 and about 100,
m and n are integers independently between 1 and about 5,000,
v is an integer greater than about 10,
x and y are integers independently between 1 and about 5,
SG is a hydrophobic moiety, with the proviso that if m is 1, then SG comprises at least 25 carbon atoms, and
NP is the nanoparticle.

12. The light-emitting device of claim 11, wherein the polymer of the polymer-nanoparticle composition comprises repeating monomer units having the formula: 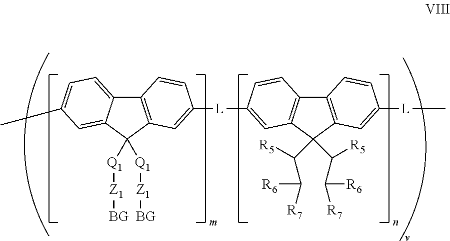
wherein:
BG is independently selected from the group consisting of primary amines, secondary amines, tertiary amines, amides, nitriles, isonitriles, cyanates, isocyanates, thiocyanates, isothiocyanates, azides, thiols, thiolates, sulfides, sulfinates, sulfonates, phosphates, hydroxyls, alcoholates, phenolates, carbonyls, carboxylates, phosphines, phosphine oxides, phosphonic acids, phosphoramides and phosphates,
L is independently a covalent bond directly linking Ar₁ and Ar₂ or a linking group selected from the group consisting of: 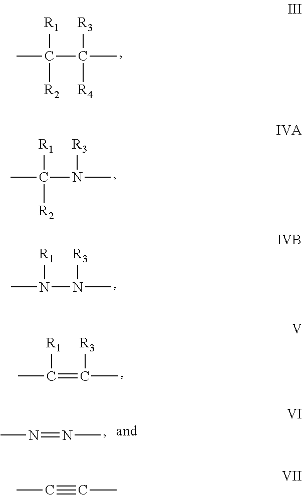
wherein R₁, R₂, R₃, R₄ are each independently selected from the group consisting of hydrogen, alkyl, substituted alkyl, heteroalkyl, alkyl, substituted alkenyl, heteroalkenyl, alkynyl, substituted alkynyl, heteroalkynyl, aryl, substituted aryl, heteroaryl,
each R₅ is independently selected from the group consisting of hydrogen, alkyl, substituted alkyl, heteroalkyl, alkyl, substituted alkenyl, heteroalkenyl, alkynyl, substituted alkynyl, heteroalkynyl, aryl, substituted aryl, heteroaryl,
each R₆ is independently selected from the group consisting of hydrogen, alkyl, substituted alkyl, heteroalkyl, alkyl, substituted alkenyl, heteroalkenyl, alkynyl, substituted alkynyl, heteroalkynyl, aryl, substituted aryl, heteroaryl, and
each R₇ is independently selected from the group consisting of alkyl of about 5 to about 50 carbon atoms, substituted alkyl of about 5 to about 50 carbon atoms, alkenyl of about 5 to about 50 carbon atoms, substituted alkenyl of about 5 to about 50 carbon atoms, alkynyl of about 5 to about 50 carbon atoms, substituted alkynyl of about 5 to about 50 carbon atoms, alkoxy of about 5 to about 50 carbon atoms, substituted alkoxy of about 5 to about 50 carbon atoms, alkenoxy of about 5 to about 50 carbon atoms, substituted alkenoxy of about 5 to about 50 carbon atoms, alkynoxy of about 5 to about 50 carbon atoms, substituted alkynoxy of about 5 to about 50 carbon atoms, thioalkyl of about 5 to about 50 carbon atoms, substituted thioalkyl of about 5 to about 50 carbon atoms, aryl of about 5 to about 50 carbon atoms, aryloxy of about 5 to about 50 carbon atoms, thioaryl of about 5 to about 50 carbon atoms, alkylaryl of about 5 to about 50 carbon atoms, and corresponding substituted counterparts and heteroatom counterparts thereof, with the proviso that, if m is 1, then at least one R₇ comprises at least 25 carbon atoms.

13. A method of enhancing homogeneity of a mixture of nanoparticles in a non-polar medium and enhancing stability of the mixture, the method comprising combining in a non-polar medium a nanoparticle and the polymer of claim 1,
wherein the number of monomer units in each block of the polymer is selected to control the stability and homogeneity of mixtures of the nanoparticle in the non-polar medium.

14. The method of claim 13, wherein one or more BG groups are bound to the nanoparticle.

15. The method of claim 13, wherein the nanoparticle comprises an element selected from the group consisting of Group 2 elements, Group 12 elements, Group 13 elements, Group 3 elements, Group 14 elements, Group 4 elements, Group 15 elements, Group 5 elements, Group 16 elements and Group 6 elements and combinations of elements from one or more of the aforementioned groups.
